(19) United States
(12) Patent Application Publication
(10) Pub. No.: US 2025/0311318 A1
(43) Pub. Date: Oct. 2, 2025

(54) POWER SILICON CARBIDE BASED SEMICONDUCTOR DEVICES HAVING SUPER JUNCTION DRIFT REGIONS AND METHODS OF FORMING SUCH DEVICES

(71) Applicant: Wolfspeed, Inc., Durham, NC (US)

(72) Inventors: Madankumar Sampath, Durham, NC (US); Woongsun Kim, Cary, NC (US); Naeem Islam, Morrisville, NC (US); Daniel J. Lichtenwalner, Raleigh, NC (US); Jeff Kim, Cary, NC (US); Sei-Hyung Ryu, Cary, NC (US)

(21) Appl. No.: 18/623,114

(22) Filed: Apr. 1, 2024

(51) Int. Cl. H01L 29/06; H01L 29/08; H01L 29/16; H01L 29/66; H01L 29/78

(52) U.S. Cl. CPC H10D 62/111; H10D 30/668; H10D 62/126; H10D 62/153; H10D 62/154; H10D 62/8325; H10D 30/0297

(57) ABSTRACT

A semiconductor device such as a MOSFET or IGBT comprises a semiconductor layer structure that comprises a drift region, a plurality of well regions having a second conductivity type on the drift region, and a plurality of source regions having a first conductivity type on the well regions. The drift region comprises a plurality of first pillars that have the first conductivity type and a first doping concentration, a plurality of second pillars that have the second conductivity type and a second doping concentration, and a plurality of third pillars that have the first conductivity type and a third doping concentration, The second and third doping concentrations exceed the first doping concentration, and the first, second and third pillars forming a super junction structure in the drift region

### FIELD

The present invention relates to semiconductor devices and, more particularly, to power semiconductor devices and to methods of fabricating such devices.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), bipolar junction transistors (“BJTs”), Insulated Gate Bipolar Transistors (“IGBT”), Schottky diodes, Junction Barrier Schottky (“JBS”) diodes, merged p-n Schottky (“MPS”) diodes, Gate Turn-Off Transistors (“GTO”), MOS-controlled thyristors and various other devices. Power semiconductor devices are often fabricated from wide band-gap semiconductor materials (herein, the term “wide band-gap semiconductor” encompasses any semiconductor having a band-gap of at least 1.4 eV) such as silicon carbide (“SiC”), which has a number of advantageous characteristics including, for example, a high electric field breakdown strength, high thermal conductivity, high electron mobility, high melting point and high-saturated electron drift velocity.

A conventional silicon carbide power semiconductor device typically has a silicon carbide substrate, such as a silicon carbide wafer having a first conductivity type (e.g., an n-type substrate), on which an epitaxial layer structure having the first conductivity type (e.g., n-type) is formed. This epitaxial layer structure (which may comprise one or more separate layers) functions as a drift region of the power semiconductor device. The device typically includes an “active region.” The active region may be formed on and/or in the drift region. The active region acts as a main junction for blocking voltage during off-state operation (also referred to as “reverse bias” or “reverse blocking” operation) and current flows through the active region during on-state operation (also referred to as “forward bias” operation). The device may also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

Power semiconductor devices are designed to block large voltage in the reverse blocking state) and to pass large currents in the forward operating state. For example, in the blocking state, a power semiconductor device may be designed to sustain hundreds or thousands of volts of electric potential, meaning that hundreds or thousands of volts of electric potential may be applied to a specified terminal of the device with negligible current flowing through the device. However, as the applied voltage approaches or passes the voltage level that the device is designed to block, non-trivial levels of current may begin to flow through the power semiconductor device. Such current, which is typically referred to as “leakage current,” may be highly undesirable. Leakage current may begin to flow if the voltage is increased beyond the designed voltage blocking capability of the device, which may be a function of, among other things, the doping concentration and thickness of the drift region. If the voltage on the device is increased past the breakdown voltage to a critical level, the increasing electric field may result in an uncontrollable and undesirable runaway generation of charge carriers within the semiconductor device, leading to a condition known as avalanche breakdown.

Power MOSFETs are perhaps the most well-known type of power semiconductor device. A power MOSFET is a three terminal device that has gate, drain and source terminals and a semiconductor body. The semiconductor body is referred to herein as a “semiconductor layer structure” and may include one or more semiconductor layers/regions. A source region that is electrically connected to the source terminal and a drain region that is electrically connected to the drain terminal are formed in the semiconductor layer structure. A channel region is interposed in the semiconductor layer structure between the source region and the drain region. A gate electrode that is electrically connected to the gate terminal is disposed adjacent the channel region and separated from the channel region by a thin oxide layer. A MOSFET may be turned on or off by setting a gate bias voltage that is applied to the gate electrode (through the gate terminal) to be above or below a threshold value. When the gate bias voltage exceeds the threshold value, the MOSFET is turned on (i.e., it is in its “on-state”), and current is conducted through the channel region between the source and drain regions. When the gate bias voltage is reduced below the threshold level, the MOSFET turns off and current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an IGBT is a semiconductor device that includes both a MOSFET and a BJT that combines the high impedance gate electrode of the MOSFET with the small on-state conduction losses that may be provided by a BJT. The base current of the BJT is supplied through the channel of the MOSFET, thereby allowing a simplified external drive circuit (since the drive circuit only charges and discharges the gate electrode of the MOSFET).

Power semiconductor devices such as power MOSFETs and BJTs can have a lateral structure or a vertical structure. In a device having a lateral structure, the terminals of the device (e.g., the drain, gate and source terminals for a power MOSFET) are on the same major surface (i.e., top or bottom) of the semiconductor layer structure. In contrast, in a device having a vertical structure, at least one terminal is provided on each major surface of the semiconductor layer structure (e.g., in a vertical MOSFET, the source and gate terminals may be on the top surface of the semiconductor layer structure and the drain terminal may be on the bottom surface of the semiconductor layer structure). The semiconductor layer structure may or may not include an underlying substrate such as a growth substrate.

Vertical power MOSFETs and IGBTs can have a planar gate electrode design in which the gate electrode of the transistor is formed above the semiconductor layer structure or, alternatively, may have a gate trench design where at least a portion of each gate electrode is formed within a gate trench in the semiconductor layer structure. With the planar gate electrode design, the channel region of each unit cell transistor is disposed underneath the gate electrode and current flows horizontally through the channel region. In contrast, in the gate trench MOSFET design, the channels are typically disposed adjacent sidewalls of the gate electrodes and current flows vertically through the channel region. Gate trench MOSFETs may provide enhanced performance, but typically require a more complicated manufacturing process.

FIG. 1A is a schematic plan view of a top surface of a portion of a semiconductor layer structure 50 of a conventional silicon carbide power MOSFET 1 that has a planar gate structure. The dotted boxes in FIG. 1A illustrate the locations of the gate electrodes that are formed on top of the semiconductor layer structure in order to provide context. FIG. 1B is a cross-sectional view taken along line 1B-1B of FIG. 1A. The cross-section of FIG. 1B shows one full unit cell of the MOSFET 1 and portions of two adjacent unit cells. It should be noted that the cross-section of FIG. 1B is not taken along a straight line but instead includes a “jog” to show cross-sections of two different regions of the MOSFET 1.

Referring to FIGS. 1A-1B, the MOSFET 1 includes a heavily-doped n-type (n+) silicon carbide semiconductor substrate 10. A lightly-doped n-type (n⁻) silicon carbide drift region 20 is provided on the upper surface of the substrate 10. An upper portion 26 of the drift region 20 may have a higher doping concentration of n-type dopants than the lower portion of the drift region 20. This more heavily-doped upper portion of the drift region 20 is typically referred to as a “current spreading layer” 26 and is considered to be part of the drift region 20. Moderately-doped (p) p-type wells 30 (also referred to as “p-wells”) are formed on or in upper portions of the n-type silicon carbide drift region 20. Upper side portions 32 of the p-wells 30 act as channel regions for the MOSFET 1, as will be explained in more detail below. The channel regions 32 may be more lightly doped than the remainder of each p-well 30. The portions of the drift region 20 (or current spreading layer 26, if provided) that are in between adjacent p-wells 30 are referred to as JFET regions 28. The JFET regions 28 are lightly to moderately doped n-type silicon carbide regions that are typically doped more heavily than the lower portion of the drift region 20, and may also be doped more heavily than the current spreading layer 26, if provided.

Heavily-doped (n⁺) n-type silicon carbide source regions 40 are formed in upper portions of the p-wells 30. In addition, heavily-doped (p⁺) p-type silicon carbide well contact regions 38 are also formed in upper portions of the p-wells 30 and appear as “islands” in the source regions 40, as can be seen best in FIG. 1A. As shown in FIG. 1B, a source metallization layer 80 is formed on the source regions 40 and the well contact regions 38. As the source regions 40 and the well contact regions 38 are heavily-doped regions, they may provide a low resistivity connection to the source metallization layer 80.

The substrate 10, drift region 20 (including any current spreading layer 26 and the JFET regions 28), the p-wells 30 (including the channel regions 32), the well contact regions 38 and the source regions 40 comprise a semiconductor layer structure 50 of MOSFET 1. A plurality of longitudinally-extending (i.e., extending in the x-direction in FIGS. 1A-1B) silicon oxide gate insulating layers 60 are formed on the upper surface of the semiconductor layer structure 50. A plurality of longitudinally-extending gate electrodes 70 are formed on the respective gate insulating layers 60 opposite the semiconductor layer structure 50. A plurality of intermetal dielectric patterns 62 cover the respective gate electrodes 70. Openings are provided between adjacent intermetal dielectric patterns 62 that expose the upper surface of the semiconductor layer structure 50. The source metallization layer 80 is formed on the intermetal dielectric patterns 62 and within these openings so as to contact the heavily-doped p-type well contact regions 38 and n-type source regions 40. A drain contact 6 is formed on the lower surface of the substrate 10. The channel regions 32 extend in the same direction (the x-direction) as the gate electrodes 70, which may be referred to herein as a longitudinal direction.

As noted above, the upper side portions of each p-well 30 serve as channel regions 32 through which current flows during on-state operation of MOSFET 1. In particular, when a voltage that exceeds a threshold voltage of MOSFET 1 is applied to the gate electrodes 70, the channel regions 32 (which are positioned directly below the gate electrodes 70 with the gate oxide layers 60 interposed therebetween) are depleted thereby allowing current to flow from a source terminal of MOSFET 1, through the source metallization layer 80 and into the source regions 40, through the depleted channel regions 32 to the JFET regions 28, and then through the drift region 20 and substrate 10 to the drain contact 6. The bold arrow in FIG. 1B illustrates the current path through the left side of the “full” unit cell shown in FIG. 1B.

FIG. 2A is a schematic plan view of a top surface of a portion of a semiconductor layer structure 150 of a conventional silicon carbide power MOSFET 100 that has a trench gate structure. FIG. 2B is a cross-sectional view taken along line 2B-2B of FIG. 2A. The cross-section of FIG. 2B shows one full unit cell of the MOSFET 100 and portions of two adjacent unit cells.

As shown in FIGS. 2A-2B, the MOSFET 100 includes a heavily-doped n-type (n⁺) silicon carbide semiconductor substrate 110. A lightly-doped n-type (n⁻) silicon carbide drift region 120 is provided on the upper surface of the substrate 110. A plurality of n-type silicon carbide JFET regions 128 are provided in the upper portion of the drift region 120. Each JFET region 128 may be more heavily doped than the remainder of the drift region 120. Moderately-doped (p) silicon carbide p-type wells 130 (also referred to as “p-wells”) are provided on the upper surfaces of the n-type JFET regions 128. Channel regions 132 (discussed below) are formed in side portions of the p-wells 130. Heavily-doped (n⁺) n-type silicon carbide source regions 140 are formed on upper portions of the p-wells 130. The substrate 110, drift region 120 (including the JFET regions 128), p-wells 130 (including the channel regions 132), and source regions 140 form part of a semiconductor layer structure 150 of the MOSFET 100.

The semiconductor layer structure 150 further includes p-type support shields 190 that extend downwardly from an upper portion (e.g., the upper surface) of the semiconductor layer structure 150. The p-type support shields 190 may be moderately (p) or heavily doped (p⁺) silicon carbide regions. As is further shown in FIG. 2B, a plurality of gate trenches 172 are formed in the upper portion of the semiconductor layer structure 150. The semiconductor layer structure 150 also includes p-type trench shielding regions 192 that are formed underneath the respective gate trenches 172, typically by implanting p-type dopants through the bottoms of the gate trenches 172. The p-type trench shielding regions 192 extend underneath the respective gate trenches 172 for all or substantially all of the length of the gate trench 172 and may be moderately (p) or heavily doped (p⁺) silicon carbide regions. The p-type support shields 190 and the p-type trench shielding regions 192 act to reduce the electric field levels that form in gate oxide layers (discussed below) during reverse blocking operation.

A gate oxide layer 160 is formed conformally within each gate trench 172, and gate electrodes 170 are formed in the gate trenches 172 on the gate oxide layers 160. An intermetal dielectric pattern 162 covers the gate electrodes 170. A source metallization layer 180 is formed on the intermetal dielectric pattern 162 and on the heavily-doped n-type source regions 140 and upper portions of the p-type support shields 190. A drain contact 106 is formed on the lower surface of the substrate 110.

### SUMMARY

Pursuant to some embodiments of the present invention, power semiconductor devices are provided that comprise a semiconductor layer structure having an active region and a termination region. The semiconductor layer structure comprises a drift region and a plurality of well regions having a second conductivity type on the drift region, each well region including a channel region. The drift region comprises a lower portion having a first conductivity type that extends throughout the active region, an upper portion having the first conductivity type that extends throughout the active region, and a super junction structure interposed between the lower and upper portions of the drift region.

In some embodiments, the super junction structure comprises a plurality of pillars having the first conductivity type and a plurality of pillars having the second conductivity type. In some embodiments, the pillars having the first have respective longitudinal axes that extend in a first direction, and the pillars having the second conductivity type have respective longitudinal axes that extend in a first direction. In some embodiments, the well regions having the second conductivity type have respective longitudinal axes that extend in the first direction, while in other embodiments, the well regions having the second conductivity type have respective longitudinal axes that extend in a second direction that is different than the first direction.

In some embodiments, the semiconductor device further comprises a substrate, and the drift region is formed on an upper surface of the substrate.

In some embodiments, the plurality of pillars having the first conductivity type comprise a plurality of first pillars that have the first conductivity type and a first doping concentration and a plurality of third pillars that have the first conductivity type and a third doping concentration, and wherein the plurality of pillars having the second conductivity type comprise a plurality of second pillars that have the second conductivity type and a second doping concentration. In some embodiments, the second and third doping concentrations exceed the first doping concentration. In some embodiments, the second and third doping concentrations each exceed the first doping concentration by at least a factor of two.

Pursuant to further embodiments of the present invention, power semiconductor devices are provided that comprise a semiconductor layer structure comprising a drift region, a plurality of well regions having a second conductivity type on the drift region, and a plurality of source regions having a first conductivity type on the well regions. The drift region comprises a first pillar that has the first conductivity type and a first doping concentration, a second pillar that has the second conductivity type and a second doping concentration, and a third pillar that has the first conductivity type and a third doping concentration, where the second and third doping concentrations exceed the first doping concentration, and the first, second and third pillars form part of a super junction structure in the drift region.

In some embodiments, the first pillar is one of a plurality of first pillars that each have the first conductivity type and the first doping concentration, the second pillar is one of a plurality of second pillars that each have the second conductivity type and the second doping concentration, and the third pillar is one of a plurality of third pillars that each have the first conductivity type and the third doping concentration.

In some embodiments, a height of each pillars is at least two microns.

In some embodiments, the second and third doping concentrations each exceed the first doping concentration by at least a factor of two.

In some embodiments, each first pillar contacts a respective one of the second pillars and a respective one of the third pillars.

In some embodiments, each second pillar is in between and contacts first and second first pillars of a respective pair of the first pillars.

In some embodiments, each third pillar is in between and contacts first and second first pillars of a respective pair of the first pillars.

In some embodiments, each second pillar is in between and contacts first and second first pillars of a respective pair of the first pillars. In some embodiments, each third pillar is in between and contacts first and second first pillars of a respective pair of the first pillars.

In some embodiments, each well region has a fourth doping concentration that is less than the second doping concentration, and each of the second pillars extends into a respective one of the well regions.

In some embodiments, the first pillars extend upwardly from a base portion of the drift region, and the base portion of the drift region has the first conductivity type and a doping concentration that exceeds the first doping concentration.

In some embodiments, a lower surface of each second pillar is a first distance above a lower surface of the drift region and a lower surface of each third pillar is a second distance above the lower surface of the drift region, where the first distance exceeds the second distance.

In some embodiments, the drift region, the well regions and the source regions each comprise silicon carbide.

In some embodiments, each third pillar extends to an upper surface of the semiconductor layer structure, and each first pillar extends to a bottom surface of one of the well regions.

In some embodiments, an upper surface of each third pillar is recessed below an upper surface of the semiconductor layer structure.

In some embodiments, the semiconductor layer structure further comprises a gate dielectric layer on an upper surface of the semiconductor layer structure and a gate electrode on the gate dielectric layer opposite the semiconductor layer structure and a first of the third pillars is underneath and vertically overlaps the gate electrode. In some embodiments, an upper portion of the first of the third pillars is in between and contacting first and second of the well regions. In some embodiments, each second pillar vertically overlaps a respective one of the source regions. In some embodiments, each first pillar vertically overlaps a respective one of the source regions.

In some embodiments, a plurality of gate trenches are provided in an upper surface of the semiconductor layer structure, the semiconductor device further comprising a plurality of gate electrodes that are in the respective gate trenches. In some embodiments, the semiconductor layer structure further comprises a plurality of trench shielding regions having the second conductivity type underneath the respective gate trenches. In some embodiments, each trench shielding region is interposed in between and vertically overlaps a respective one of the third pillars and a respective one of the gate trenches. In some embodiments, each third pillar is self-aligned with a respective one of the gate trenches and/or with a respective one of the trench shielding regions.

In some embodiments, at least a portion of each second pillar is charge balanced with a portion of a composite pillar, where the composite column comprises a respective pair of the first pillars and a respective one of the third pillars.

Pursuant to still further embodiments of the present invention, semiconductor devices are provided that comprise a semiconductor layer structure comprising a drift region that includes first and second lower-doped first pillars that have a first conductivity type, first and second higher-doped second pillars that have a second conductivity type, and a higher-doped third pillar that has the first conductivity type, first and second well regions having the second conductivity type on the drift region, and a gate dielectric layer on an upper surface of the semiconductor layer structure and contacting upper surfaces of the first and second well regions. In these semiconductor devices, the higher-doped third pillar is in between the first and second well regions and is in between and contacting the first and second lower-doped first pillars.

The semiconductor device may further comprise a gate electrode that has a longitudinal axis that extends in a first direction, where the gate electrode is not recessed within the semiconductor layer structure.

In some embodiments, the first and second lower-doped first pillars, the first and second higher-doped second pillars and the higher-doped third pillar each have respective longitudinal axes that extend in the first direction.

In some embodiments, the first lower-doped first pillar vertically overlaps the first well region and the second lower-doped first pillar vertically overlaps the second well region.

In some embodiments, the first lower-doped first pillar is in between and contacting the first higher-doped second pillar and the higher-doped third pillar.

In some embodiments, the first and second lower-doped first pillars, the first and second higher-doped second pillars and the higher-doped third pillar together form a super junction structure in the drift region.

In some embodiments, lower surfaces of first and second higher-doped second pillars are at a first distance above a lower surface of the drift region and a lower surface of the higher-doped third pillar is at a second distance above the lower surface of the drift region, where the first distance exceeds the second distance.

In some embodiments, at least a portion of the first higher-doped second pillar is charge balanced with a portion of a composite pillar, where the composite column comprises the first and second lower-doped first pillars and the higher-doped third pillar.

In some embodiments, the first and second higher-doped second pillars and the higher-doped third pillar each have respective doping concentrations that exceed a doping concentration of the first lower-doped first pillar by at least a factor of five.

In some embodiments, the first and second lower-doped pillars extend upwardly from a base portion of the drift region, and the base portion of the drift region has the first conductivity type and a doping concentration that exceeds a doping concentration of the first and second lower-doped pillars.

In some embodiments, the higher-doped third pillar extends upwardly to an upper surface of the semiconductor layer structure, and the first lower-doped first pillar extends upwardly to a bottom surface of the first well region.

In some embodiments, an upper surface of the higher-doped third pillar is recessed below an upper surface of the semiconductor layer structure.

In some embodiments, the semiconductor layer structure further comprises a gate dielectric layer having a planar bottom surface that extends on an upper surface of the semiconductor layer structure and a gate electrode on the gate dielectric layer opposite the semiconductor layer structure, and a first of the third pillars is underneath and vertically overlaps the gate electrode.

In some embodiments, a first source region having the first conductivity type is provided in the first well region and a second source region having the first conductivity type is provided in the second well region, and the first lower-doped first pillar vertically overlaps the first source region and the second lower-doped first pillar vertically overlaps the second source region. In some embodiments, the first higher-doped second pillar vertically overlaps the first source region and the second higher-doped second pillar vertically overlaps the second source region. In some embodiments, the first source region is closer to the higher-doped third pillar than is the first of the higher-doped second pillars. In some embodiments, the first and second lower-doped first pillars, the first and second higher-doped second pillars and the higher-doped third pillar each have longitudinally-extending sidewalls that extend perpendicularly to an upper surface of the semiconductor layer structure.

According to still further embodiments of the present invention, semiconductor devices are provided that comprise a semiconductor layer structure comprising a drift region and first and second well regions having a second conductivity type on the drift region. The drift region comprises a pair of first pillars that have a first conductivity type and a first doping concentration, a second pillar that has the second conductivity type and a second doping concentration, and a third pillar that has the first conductivity type and a third doping concentration, where the second and third doping concentrations exceed the first doping concentration. The third pillar is in between and contacting the two first pillars in the pair of first pillars so that the pair of first pillars and the third pillar form a composite pillar. A first portion of the second pillar horizontally overlaps a first portion of the composite pillar and is charge balanced with the first portion of the composite pillar.

In some embodiments, the second and third doping concentrations each exceed the first doping concentration by at least a factor of five.

In some embodiments, the second pillar contacts one of the first pillars in the pair of first pillars.

In some embodiments, a lower surface of the second pillar is a first distance above a lower surface of the drift region and a lower surface of the third pillar is a second distance above the lower surface of the drift region, where the first distance is within 10% of the second distance.

In some embodiments, the third pillar extends to an upper surface of the semiconductor layer structure, and each first pillar in the pair of first pillars extends to a bottom surface of a respective one of the first and second well regions.

In some embodiments, the semiconductor layer structure further comprises a gate dielectric layer having a planar bottom surface that extends on an upper surface of the semiconductor layer structure and a gate electrode on the gate dielectric layer opposite the semiconductor layer structure, and the third pillar is underneath and vertically overlaps the gate electrode.

In some embodiments, an upper portion of the third pillar is in between and contacting first and second of the well regions.

In some embodiments, a gate trench is provided in an upper surface of the semiconductor layer structure, the semiconductor device further comprising a gate electrode that is within the gate trench. In some embodiments, the semiconductor layer structure further comprises a trench shielding region having the second conductivity type underneath the gate trench. In some embodiments, the trench shielding region is interposed in between and vertically overlaps the third pillar and the gate trench. In some embodiments, the third pillar is self-aligned with the gate trench. In some embodiments, the third pillar is self-aligned with the trench shielding region.

Pursuant to additional embodiments of the present invention, semiconductor devices are provided that comprise a semiconductor layer structure comprising a drift region, a plurality of well regions having a second conductivity type on the drift region, and a plurality of source regions having a first conductivity type on the well regions. The drift region comprises a plurality of first pillars that have the first conductivity type and a first doping concentration, a plurality of second pillars that have the second conductivity type and a second doping concentration, and a plurality of third pillars that have the first conductivity type and a third doping concentration, where the second and third doping concentrations exceed the first doping concentration. A height of each third pillar is at least two microns.

In some embodiments, the second and third doping concentrations each exceed the first doping concentration by at least a factor of two.

In some embodiments, each first pillar contacts a respective one of the second pillars and a respective one of the third pillars.

In some embodiments, each second pillar is in between and contacts first and second first pillars of a respective pair of the first pillars.

In some embodiments, each third pillar is in between and contacts first and second first pillars of a respective pair of the first pillars.

In some embodiments, a lower surface of each second pillar is a first distance above a lower surface of the drift region and a lower surface of each third pillar is a second distance above the lower surface of the drift region, where the first distance is within 10% of the second distance.

In some embodiments, each third pillar extends to an upper surface of the semiconductor layer structure, and each first pillar extends to a bottom surface of one of the well regions.

In some embodiments, a plurality of gate trenches are provided in an upper surface of the semiconductor layer structure, the semiconductor device further comprising a plurality of gate electrodes that are in the respective gate trenches. In some embodiments, the semiconductor layer structure further comprises a plurality of trench shielding regions having the second conductivity type underneath the respective gate trenches. In some embodiments, each trench shielding region is interposed in between and vertically overlaps a respective one of the third pillars and a respective one of the gate trenches. In some embodiments, each third pillar is self-aligned with a respective one of the gate trenches. In some embodiments, each third pillar is self-aligned with a respective one of the trench shielding regions.

According to still further embodiments of the present invention, methods of fabricating a semiconductor device are provided in which a semiconductor layer structure is provided that includes a drift region having a first conductivity type, a well layer having a second conductivity type on the drift region, and a source layer having the first conductivity type on the well layer. A first mask is used to implant second conductivity type dopants into the semiconductor layer structure to form first and second higher-doped second conductivity type second columns within the drift region. A second mask is used to form a gate trench in the semiconductor layer structure and to implant first conductivity type dopants into the semiconductor layer structure to form a higher-doped third column within the drift region underneath the gate trench. The higher-doped third column is in between the first and second higher-doped second columns and spaced apart from each of the first and second higher-doped second columns by respective lower-doped first pillars that have the first conductivity type, and the first, second and third pillars form a super junction structure in the drift region.

These methods may further comprise using the second mask to implant second conductivity type dopants into the semiconductor layer structure to form a trench. shielding region underneath the gate trench.

In some embodiments, the higher-doped third column and the trench shielding region vertically overlap the gate trench and the trench shielding region is in between the gate trench and the higher-doped third column.

In some embodiments, the gate trench is formed before the first conductivity type dopants are implanted into the semiconductor layer structure to form the higher-doped third column.

### BRIEF DESCRIPTION OF DRAWINGS

FIG. 1A is a schematic plan view of a portion of a top surface of a semiconductor layer structure of a conventional vertical power MOSFET that has a planar gate design.

FIG. 1B is a schematic cross-sectional view taken along the line 1B-1B of FIG. 1A with portions of the upper metallization and dielectric layers of the power MOSFET added for context.

FIG. 2A is a schematic plan view of a portion of a top surface of a semiconductor layer structure of a conventional vertical power MOSFET that has a trench gate design.

FIG. 2B is a schematic cross-sectional view taken along the line 2B-2B of FIG. 2A with portions of the upper metallization and dielectric layers of the power MOSFET added for context.

FIG. 3A is a schematic top view of a vertical silicon carbide power MOSFET according to certain embodiments of the present invention that has a planar gate design.

FIG. 3B is a schematic top view of the power MOSFET of FIG. 3A with various of the upper metal and dielectric layers removed.

FIG. 3C is a schematic top view of the portion of the power MOSFET of FIG. 3B shown in the box labelled A in FIG. 3B.

FIG. 3D is a schematic cross-sectional view taken along the line 3D-3D of FIG. 3C with portions of the upper metallization and dielectric layers of the power MOSFET added for context.

FIG. 4A is a schematic cross-sectional view that illustrates the portion of the drift region of the conventional power MOSFET of FIGS. 1A-1B in which electric fields exceeding a first (arbitrary) level are present during reverse blocking operation.

FIG. 4B is a schematic cross-sectional view that illustrates the portion of the drift region of the power MOSFET of FIGS. 3A-3D in which electric fields exceeding the first (arbitrary) level are present during reverse blocking operation.

FIGS. 5A and 5B are a schematic plan view and a cross-sectional view that correspond to FIGS. 3C and 3D, respectively, that illustrate a modified version of the power MOSFET of FIGS. 3A-3D.

FIGS. 6A and 6B are a schematic plan view and a cross-sectional view that correspond to FIGS. 3C and 3D, respectively, that illustrate another modified version of the power MOSFET of FIGS. 3A-3D.

FIGS. 7A and 7B are a schematic plan view and a cross-sectional view that correspond to FIGS. 3C and 3D, respectively, that illustrate yet another modified version of the power MOSFET of FIGS. 3A-3D.

FIG. 8A is a schematic plan view of a portion of a top surface of a semiconductor layer structure of a power MOSFET according to further embodiments of the present invention that has a trench gate design.

FIG. 8B is a schematic cross-sectional view taken along the line 8B-8B of FIG. 8A with portions of the upper metallization and dielectric layers of the power MOSFET added for context.

FIGS. 9A and 9B are a schematic plan view and a cross-sectional view that correspond to FIGS. 8A and 8B, respectively, that illustrate a modified version of the power MOSFET of FIGS. 8A-8B.

FIGS. 10A and 10B are a schematic plan view and a cross-sectional view that correspond to FIGS. 8A and 8B, respectively, that illustrate another modified version of the power MOSFET of FIGS. 8A-8B.

FIGS. 11A-11F are schematic cross-sectional views illustrating a method of fabricating the power MOSFET of FIGS. 8A-8B.

FIG. 12A is a schematic top view of the upper surface of a semiconductor layer structure of a power MOSFET according to further embodiments of the present invention.

FIGS. 12B and 12C are cross-sectional views taken along lines 12B-12B and 12C-12C, respectively, of FIG. 12A with portions of the upper metallization and dielectric layers of the power MOSFET added for context.

FIGS. 13A and 13B are schematic cross-sectional views of power MOSFETs according to still further embodiments of the present invention.

FIG. 14A is a schematic top view of the upper surface of a semiconductor layer structure of a power MOSFET having a cell configuration according to further embodiments of the present invention.

FIG. 14B is a cross-sectional view taken along line 14B-14B of FIG. 14A that also includes some of the upper metallization and dielectric layers to provide additional context.

FIGS. 15A and 15B illustrate two example graded doping profiles that can be used for the higher-doped p-type pillars and the higher-doped n-type pillars in the modified super junction structures according to embodiments of the present invention.

FIG. 16 is a schematic cross-sectional view of the semiconductor layer structure of a semiconductor device according to embodiments of the present invention that has a super junction structure that is buried within a drift region.

Herein, two part reference numerals that include a reference number followed by a dash and an instance number may be used to identify certain elements shown in the figures where multiple instances of the element are shown. The first part of the two part reference numeral may be used to refer to these elements collectively while the full reference number may be used to refer to individual instances of the element.

### DETAILED DESCRIPTION

The blocking voltage of a power semiconductor device refers to the voltage that can be applied to a specified terminal of the semiconductor device (e.g., the drain terminal for a power MOSFET) while maintaining the leakage currents below specified levels. In vertical power semiconductor devices, the blocking voltage rating of the device is typically determined by the thickness and the doping concentration of the drift region. The blocking voltage rating can be increased by decreasing the doping concentration of the drift region and/or by increasing the thickness of the drift region. Typically, during the design phase, a desired blocking voltage rating is selected, and then the thickness and doping concentration of the drift region are chosen that will achieve the desired blocking voltage rating. Since the drift region is the current path for the device in the forward “on” state, the decreased doping concentration and/or increased thickness of the drift region may result in a higher on-state resistance for the device. Thus, there is an inherent tradeoff between the on-state resistance and blocking voltage for power semiconductor devices.

Power semiconductor devices are used in applications where the device is used to block hundreds of even thousands of volts during reverse blocking operation. As discussed above, the depth of the drift region may be increased and/or the doping concentration of the drift region may be reduced to increase the blocking voltage rating of the device. These changes, however, increase the current path and/or reduce the conductivity of the drift region, which increases the on-state resistance of the drift region. In contrast, the on-state resistance of the source regions, the channel regions and the substrate typically remains constant as a function of the reverse blocking voltage of a power semiconductor device. Thus, for high blocking voltage rating power semiconductor devices, the on-state resistance may be driven by the resistance of the drift region. An increased on-state resistance may increase conduction losses and/or reduce switching speeds, both of which are undesirable.

One known technique for increasing the blocking voltage of a power semiconductor device while reducing the impact thereof on the on-state resistance is to use a so-called super junction drift region. In a drift region having a super junction structure, the drift region is divided into alternating, side-by-side n-type and p-type regions, where these regions are more heavily doped than normal. The increase n the amount of doping may vary based on device type and application. For example, the increased doping concentration may be between twice and two hundred times the normal doping concentration. These side-by-side n-type and p-type regions are often referred to as “pillars.” The pillars typically have fin shapes (i.e., each pillar is a stripe of material having a selected conductivity type that has a predetermined width and depth and that extends longitudinally through the device). However, the pillars may have other shapes such as, for example, column shapes (e.g., a horizontal cross-section through the drift region may appear as a checkerboard arrangement of n-type and p-type columns). The number of charge carriers in each n-type pillar may be approximately equal to the number of charge carriers in each p-type pillar (e.g., within 20% or, more preferably, within 10% or within 5% or within 2%). The number of charge carriers in each pillar may be set by selecting the width and doping concentration of each pillar. When the number of charge carriers in adjacent n-type and p-type pillars are approximately equal, the interface between the pillars will laterally deplete during reverse blocking operation, which acts to change the shape of the electric field that forms in the drift region during reverse blocking operation. In particular, the portion of the electric field that exceeds a first level will have a generally rectangular shape in a super junction style drift region, whereas in a non-super junction style drift region the portion of the electric field that exceeds the first level has more of a triangular shape as the electric field extends upwardly from the drain electrode in between the well regions. The generally rectangular electric field that forms in a super junction style drift region acts to better spread the electric field throughout the lower portion of the drift region, which reduces the electric field values in upper portions of the semiconductor layer structure where high electric field values can increase leakage currents during reverse blocking operation and/or slowly damage the gate dielectric layers (which can eventually lead to device failure). Thus, super junction style drift regions may exhibit superior performance during reverse blocking operation. Moreover, since the n-type pillars may be more heavily-doped than a normal drift region, the resistance of a super junction style drift region during on-state operation may be less than that of a conventional drift region. While the p-type pillars may cause some degree of current crowding in the drift region, the significantly increased doping concentration of the n-type pillars provides an overall improvement in the conductivity of the drift region, and hence a decrease in the on-state resistance. Thus, super junction style drift regions may also exhibit improved performance during on-state operation.

Thus, by using a super junction style drift region, the conventional tradeoff between the breakdown voltage of the device and the doping level of the drift region may be avoided. Typically, at least some of the pillars are formed via ion implantation, and a high-energy “deep” ion implantation process are typically used (e.g., that will result in ion implantation depths of 2.5 microns to 5 microns or more) to enhance the effect of the super junction structure. In devices with super junction drift regions, the doping concentration in the drift region may be increased in order to reduce the on-state resistance of the device with reduced effect on the blocking voltage rating of the device.

A conventional super junction structure comprises alternating pillars of heavily-doped n-type and p-type material that are quasi-charge balanced, meaning that charge of each p-type pillars is approximately equal to the charge of each n-type pillar, where approximately equal means within 20%). However, if the width of each pillar (i.e., the extent of the pillar in the transverse direction) is made relatively large, then during reverse blocking operation the electric fields may extend upwardly somewhat more in the first conductivity type pillars (the pillars having the opposite conductivity type of the channel regions), and these electric fields can stress the gate oxide layers over time, ultimately resulting in device failure. Conversely, if the widths of each pillar in the transverse direction is made relatively small, then the current density is increased during on-state operation (due to the reduced size of the JFET gaps), which may increase the on-state resistance.

Pursuant to embodiments of the present invention, vertical power silicon carbide MOSFETs and other vertical power semiconductor devices (e.g., IGBTs) are provided that have drift regions that include modified super junction structures. These modified super junction structures may provide improved performance and may be easier to fabricate than conventional super junction structures. While super junction structures can provide improved performance, they often are not used because they increase the fabrication cost for a semiconductor device and/or may be difficult to form. The easier to fabricate super junction structures disclosed herein thus may facilitate wider adoption of super junction style drift regions.

Power semiconductor devices having drift regions with super junction structures can be formed via either epitaxial growth or ion implantation. When formed via epitaxial growth, a drift region is grown on a wafer. The drift region has a first conductivity type with at least an upper portion of the drift region having a doping concentration that is desired for the first conductivity type pillars. Then, the wafer is removed from the growth apparatus and selectively etched to form trenches in the drift region where the second conductivity type pillars will be formed. This etching process forms a plurality of first conductivity type pillars in an upper portion of the drift region that are separated by the trenches. The wafer is then placed back in the growth apparatus, and semiconductor material having the second conductivity type is then grown in the trenches to form the second conductivity type pillars. Unfortunately, this technique may increase the fabrication costs as compared to devices that do not have super junction style drift regions. Moreover, it may be difficult in silicon carbide devices to perform the requisite deep trench etching followed by regrowth in the trenches with precise doping control.

There are two different techniques available for forming power semiconductor devices having drift regions with super junction structures using ion implantation. With the first technique, the drift region is grown to have a first conductivity type with at least an upper portion of the drift region having a doping concentration that is desired for the first conductivity type pillars. Then, the wafer is removed from the growth apparatus and a selective ion implantation process is performed to implant second conductivity type dopants into at least the upper portions of the drift region. This ion implantation step forms the second conductivity type pillars while simultaneously forming the first conductivity type pillars. In practice, it may be difficult with this approach to obtain a proper charge balance between the first and second conductivity type pillars, as it is difficult to set the dose for the second conductivity type dopants so that the second conductivity type implant overcomes the first conductivity type dopants that are already present in the drift region from the epitaxial growth process and is further doped to a level that matches the doping concentration of the first conductivity type pillars. This may particularly be the case if channeled ion implantation techniques are used. As such, the super junction structure may in practice not have good charge balance, which may degrade the performance of the device during reverse blocking operation.

According to the second technique for forming power semiconductor devices having drift regions with super junction structures using ion implantation, the upper portion of the drift region may be grown as an undoped layer or a lightly doped layer. Then, the wafer is removed from the growth apparatus and a first selective ion implantation process is performed to implant first conductivity type dopants into the upper portion of the drift region to form a plurality of first conductivity type pillars in the drift region. Next, a second ion implantation process is performed to implant second conductivity type dopants into the upper portion of the drift region between the first conductivity type pillars in order to form the second conductivity type pillars in the drift region. While this technique may work well when conventional (random) ion implantation techniques are used, it does not work well when channeled ion implantation processes are used, as straggle from the first ion implantation step will reduce the ability of the second ion implantation process to implant the dopants along the channels in the semiconductor lattice. As will be discussed in more detail below, the use of channeled ion implants to form the super junction structure may be preferred, particularly in devices with high voltage blocking requirements, as channeled ion implants may be used to form much deeper implanted regions while reducing damage to the semiconductor material.

Thus, for the reasons discussed above, it may not be possible to fabricate power semiconductor devices in a commercially practical manner that have drift regions with deep super junction structures while ensuring that the super junction structure has good charge balance using conventional techniques.

The modified super junction style drift regions according to embodiments of the present invention that are disclosed herein may have drift regions with deep super junction structures while exhibiting good charge balance These modified super junction style drift regions may include a plurality of lower-doped first pillars of first conductivity type material, a plurality of higher-doped second pillars of second conductivity type material, and a plurality of higher-doped third pillars of first conductivity material. Herein the terms “lower-doped” and higher-doped”, when used to describe the doping concentration of pillars of a super junction structure, do not specify a particular doping concentration range but instead are used to specify the relative doping concentrations. In particular, a higher-doped pillar of a super junction structure has a doping concentration that is greater than (e.g., at least twice the doping concentration in example embodiments) of any lower-doped pillars in the super junction structure. A pair of lower-doped first pillars of first conductivity type material may surround each higher-doped third pillar of first conductivity material to form a composite pillar that is a first conductivity type region that has both lower-doped and higher-doped portions. A pair of higher-doped second pillars of second conductivity type material may surround each composite pillar of first conductivity type material so that the super junction style drift region has alternating first conductivity type and second conductivity type regions.

In some embodiments of the present invention, the modified super junction style drift regions may extend into the upper portion of the semiconductor layer structures of the power semiconductor devices. For example, the pillars of the super junction structures may extend into the well and/or JFET regions of a power MOSFET or IGBT. In other embodiments, the super junction structure may be formed independently of the device structure. For example, the super junction structure may be buried in the drift region so that it does not extend into, for example, the well and/or JFET regions. In such embodiments, the super junction structure may have a wide variety of configurations (e.g., longitudinally extending fins of p=type and n-type material, checkerboard patterns, etc.) and/or a wide variety of orientations (e.g., longitudinal axes of the pillars need not extend in the same direction as longitudinal axes of elements of the device such as gate electrodes).

The power semiconductor devices according to embodiments of the present invention may be easier to fabricate than conventional devices having super junction style drift regions, and/or may achieve better charge balance between the p-type and n-type pillars of the super junction structure. In addition, channeled ion implantation techniques may be used to form the pillars of the super junction structure, allowing for very deep super junction structures that can block very high voltage levels during reverse blocking operation.

As will be discussed in greater detail below, the techniques disclosed herein may be used in power MOSFETs and IGBTs having either planar gate electrodes or trench gate designs.

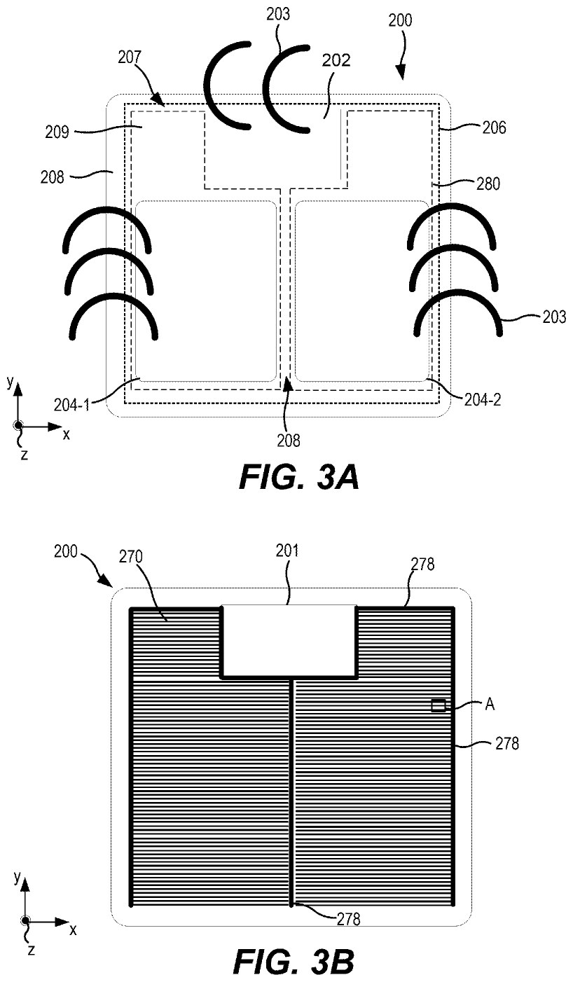

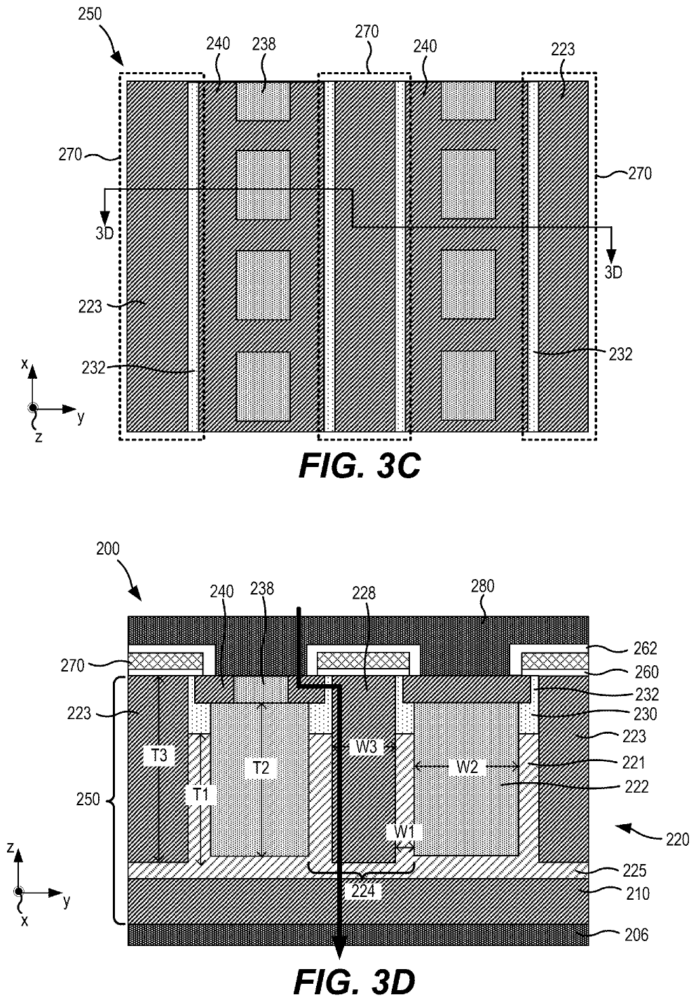

Example power semiconductor devices according to embodiments of the present invention will now be described with reference to FIGS. 3A-14. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top (plan) view of a vertical silicon carbide power MOSFET 200 according to certain embodiments of the present invention. FIG. 3B is a schematic plan view of the power MOSFET 200 with various top-side metal and dielectric layers thereof omitted to show the gate electrodes and gate buses. FIG. 3C is a schematic top view of the portion of the power MOSFET 200 of FIG. 3B shown in the box labelled A in FIG. 3B. FIG. 3D is a schematic cross-sectional view of about two unit cells of the power MOSFET 200 that is taken along line 3D-3D of FIG. 3C. It will be appreciated that the thicknesses of various of the layers and regions in FIGS. 3A-3D are not necessarily drawn to scale. The same is true with respect to the other figures included in this application.

The power MOSFET 200 includes a semiconductor layer structure 250 (see FIGS. 3C-3D) that comprises one or more semiconductor substrates and/or layers. At least one of the semiconductor layers in the semiconductor layer structure 250 may be a silicon carbide layer. Various metal and/or dielectric layers are formed on either side of the semiconductor layer structure 250 and/or embedded in the semiconductor layer structure 250.

As shown in FIG. 3A, the top-side metal layers include a gate bond pad 202 and one or more source bond pads 204-1, 204-2 that are formed on the upper side of the semiconductor layer structure 250. A metal drain pad 206 (shown as a dotted box in FIG. 3A, and fully visible in FIG. 3D) is provided on the bottom side of the semiconductor layer structure 250. The gate bond pad 202, the source bond pads 204 and the drain pad 206 form the respective gate, source and drain terminals of power MOSFET 200. The gate and source pads 202, 204 may each be formed of a metal, such as aluminum, that bond wires can be readily attached to via conventional techniques such as thermo-compression or soldering. The drain pad 206 may likewise be a metal pad. A protective layer 209 such as a polyimide layer may cover the entire upper surface of power MOSFET 200 except for the gate and source bond pads 202, 204.

Still referring to FIG. 3A, the power MOSFET 200 includes a source metallization layer 280 (indicated by the dashed boxes in FIG. 3A) that electrically connects certain regions of the semiconductor layer structure 250 to the source bond pads 204. The source bond pads 204 may be portions of the source metallization layer 280 that are exposed through openings in the protective layer 209 or may be separate metal pads. The source metallization layer 280 may generally overlie or correspond to an “active region” 207 of the power MOSFET 200 where the unit cell transistors are located. An inactive region 208 of power MOSFET 200 surrounds the active region 207. The inactive region 208 may include a termination region that extends around the periphery of the MOSFET 200 that includes guard rings, junction termination elements or other termination structures (not shown), a gate pad region that underlies the gate pad 202, and gate bus regions (discussed below).

Bond wires 203 are shown in FIG. 3A that may be used to connect the gate bond pad 202 and the source bond pads 204 to external circuits or the like. The drain pad 206 on the bottom side of power MOSFET 200 may be connected to an external circuit through, for example, an underlying submount (not shown).

FIG. 3B is another plan view of power MOSFET 200 with the gate and source bond pads 202, 204, the polymide layer 209, the source metallization layer 280, and various other metal and/or dielectric layers removed to show the gate electrodes 270 that are formed on the upper surface of the semiconductor layer structure 250. A patterned field oxide layer (not shown) is formed on the semiconductor layer structure 250 in the inactive region 208 of the MOSFET 200. The field oxide layer may be a relatively thick oxide layer (e.g., ten to twenty times thicker than the gate oxide layers that are discussed below). A polysilicon layer 201 may be formed on the field oxide layer and may be formed in the region where the gate bond pad 202 is formed so that the gate bond pad 202 vertically overlaps the field oxide layer and the polysilicon layer 201. As used herein, two elements of a semiconductor device are considered to “vertically overlap” if an axis that is perpendicular to the major surfaces of the semiconductor layer structure of the semiconductor device intersects both elements.

One or more gate buses 278 are provided that extend around the periphery of the active region 207 and/or through the active region 207. The field oxide layer also typically runs underneath each gate bus 278. The gate buses 278 are electrically connected to the gate bond pad 202, often through gate resistors (not shown). A plurality of gate electrodes 270 are formed throughout the active region 207 on the upper surface of the semiconductor layer structure 250. In the depicted power MOSFET 200, the gate electrodes 270 extend in the x-direction across the semiconductor layer structure 250. In other cases, the gate electrodes 270 may extend in the y-direction across the semiconductor layer structure 250, or the gate electrodes 270 can extend in both the x-direction and in the y-direction to form a grid-like gate electrode structure. The gate electrodes 270 may be connected to the gate pad 202 through the gate buses 278. The gate electrodes 270 may comprise, for example, a doped polysilicon pattern. The gate buses 278 may comprise polysilicon and/or metal structures in example embodiments and typically are in the inactive region 208 of power MOSFET 200.

FIG. 3C is a schematic top view of the upper surface of the semiconductor layer structure 250 of the portion of the silicon carbide power MOSFET 200 of FIG. 3B that is shown in the box labelled A in FIG. 3B. It should be noted that the view of FIG. 3C is rotated 90° relative to the box A in FIG. 3B. The dotted boxes in FIG. 3C illustrate the locations of the gate electrodes 270. FIG. 3D is a cross-sectional view taken along line 3D-3D of FIG. 3C. The cross-section of FIG. 3D shows one full unit cell of the MOSFET 200 and portions of two adjacent unit cells. It should be noted that the cross-section of FIG. 3D is not taken along a straight line but instead includes a “jog” to show cross-sections of two different regions of the MOSFET 200. Note that FIG. 3D illustrates various of the metal and dielectric layers that are formed on the upper surface of the semiconductor layer structure 250.

Referring to FIGS. 3C-3D, the power MOSFET 200 includes an n-type silicon carbide semiconductor substrate 210 such as, for example, a heavily-doped (n⁺) single crystal 4H silicon carbide semiconductor substrate. The n-type doping concentration of the substrate 210 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., either n-type or p-type) that are present within a cubic centimeter of semiconductor material as measured using standard measurement techniques such as Secondary Ion Mass Spectrometry (“SIMS”). The doping concentration of a layer or region may be relatively constant or may vary (e.g., be graded with depth), and the doping concentration refers to the peak doping concentration of the layer or region. For an n-type semiconductor material, references to the doping concentration refer to the concentration of n-type dopants and for a p-type semiconductor material, references to the doping concentration refer to the concentration of p-type dopants. The substrate 210 may be any appropriate thickness (e.g., between 100 and 500 microns thick), and it will be appreciated that the substrate 210 will typically be much thicker than shown. The thickness of various other layers of power MOSFET 200 likewise may not be shown to scale in order to allow other portions of the devices to be enlarged in the figures. The substrate 210 may be partially or fully removed in some embodiments.

A silicon carbide drift region 220 is provided on the upper surface of the substrate 210. The silicon carbide drift region 220 may be a thick region, having a vertical height above the substrate 210 of, for example, 3-150 microns. The silicon carbide drift region 220 has a super junction structure and will be described in greater detail below.

A plurality of moderately-doped (p) p-type well regions 230 (which may also be referred to herein as a “p-wells 230”) are formed on the n-type drift region 220 throughout the active region 207. The p-wells 230 may have doping concentrations of, for example, between 5×10¹⁵ cm⁻³ and 5×10¹⁹ cm⁻³ and, more typically, between 5×10¹⁶ cm⁻³ and 5×10¹⁹ cm⁻³. Channel regions 232 are provided in upper side portions of the p-wells 230. A plurality of heavily-doped n-type silicon carbide source regions 240 are formed in upper portions of the respective p-wells 230. The source regions 240 may have doping concentrations of, for example, between 5×10¹⁷ cm⁻³ and 5×10²¹ cm⁻³. In addition, heavily-doped p-type silicon carbide well contact regions 238 are also formed in upper portions of the p-wells 230 adjacent the source regions 240. The well contact regions 238 may appear as a plurality of “islands” in the source region 240 when the MOSFET 200 is viewed in plan view, as shown in FIG. 3C. In other embodiments, the well contact regions 238 may extend as stripes in the x-direction, or may have other configurations. The substrate 210, the drift region 220, the p-wells 230 (including the channel regions 232) the well contact regions 238 and the source region 240 together comprise the semiconductor layer structure 250 of MOSFET 200.

As shown in FIG. 3D, the silicon carbide drift region 220 may have a modified super junction structure. In particular, the silicon carbide drift region 220 includes a plurality of lower-doped first pillars 221 of n-type material, a plurality of higher-doped second pillars 222 of p-type material, and a plurality of higher-doped third pillars 223 of n-type material. In example embodiments, the higher-doped p-type second pillars 222 and the higher-doped n-type third pillars 223 may have respective p-type and n-type doping concentrations in the range of 5×10¹⁵ atoms/cm³ to 1×10¹⁹ atoms/cm³ or in the range of 5×10¹⁶ atoms/cm³ to 1×10¹⁸ atoms/cm³ or in in the range of 8×10¹⁶ atoms/cm³ to 5×10¹⁷ atoms/cm³. The lower-doped n-type first pillars 221 may have an n-type doping concentration that is in the range of 5×10¹⁴ atoms/cm³ to 1×10¹⁸ atoms/cm³ in some embodiments. In other embodiments, the lower-doped n-type first pillars 221 may have an n-type doping concentration that is in the range of 1×10¹⁵ atoms/cm³ to 5×10¹⁶ atoms/cm³ or 1×10¹⁵ atoms/cm³ to 1×10¹⁶ atoms/cm³ or 1×10¹⁶ atoms/cm³ to 1×10¹⁸ atoms/cm³. In some embodiments, the n-type doping concentration of the lower-doped first pillars 221 may be at least two times, at least three times, at least five times or at least ten times less than the p-type doping concentration of the higher-doped p-type second pillars 222 and/or the n-type doping concentration of the higher-doped n-type third pillars 223. As noted above, herein the first pillars 221 may be referred to as “lower-doped first pillars 221” as a doping concentration of each first pillar 221 is less than half the doping concentration (and typically about an order of magnitude less than) the doping concentrations of the second pillars 222 and the third pillars 223. Similarly, the second pillars 222 may be referred to as “higher-doped second pillars 222” and the third pillars 223 may be referred to as “higher-doped third pillars 223” since the doping concentration of each second pillar 222 is more than twice the doping concentration (and typically about an order of magnitude or more than) the doping concentration of each first pillar 221 and the doping concentration of each third pillar 223 is more than twice the doping concentration (and typically about an order of magnitude or more than) the doping concentration of each first pillar 221. A doping concentration of the second pillars 222 may be the same as or different than (either higher or lower) the doping concentration of the third pillars 223.

Each of the first pillars 221, the second pillars 222 and the third pillars 223 may be stripes of material that have longitudinal axes that extend in the longitudinal direction (the x-direction, which is the same direction as the longitudinal axes of the gate electrodes of power MOSFET 200), and have respective widths W1, W2, W3 in the transverse direction (the y-direction) and respective thicknesses T1, T2, T3 in the depth direction (the z-direction). The width W1 of each first pillar 221 may be the same as or different than the widths W2 and/or W3 of the second pillars 222 and the third pillars 223, respectively, and the width W2 of each second pillar 222 may be the same as or different than the width W3 of each third pillar 223. Similarly, the thickness T1 of each first pillar 221 may be the same as or different than the thicknesses T2 and/or T3 of the second pillars 222 and the third pillars 223, respectively, and the thickness T2 of each second pillar 222 may be the same as or different than the thickness T3 of each third pillar 223. As shown in FIG. 3D, in some embodiments the third pillars 223 may extend closer to the substrate 210 than do the second pillars 222. This arrangement may ensure that the p-type pillars 222 are fully depleted during reverse blocking operation.

As shown in FIG. 3D, a pair of lower-doped n-type first pillars 221 are formed on either side of each higher-doped n-type third pillar 223. Each pair of lower-doped n-type first pillars 221 and the higher-doped n-type third pillar 223 therebetween form a respective composite n-type pillar 224. A pair of higher-doped p-type second pillars 222 are formed on either side of each composite n-type pillar 224. Consequently, the drift region 220 includes alternating p-type second pillars 222 and composite n-type pillars 224. As shown in FIG. 3D, the pillars 221-224 need not extend downwardly all of the way to the lower surface of the drift region 220 so that the lower portion of the drift region 220 may be a continuous lower-doped n-type region 225. In some embodiments, the lower portion 225 of the drift region 220 may be more heavily doped than the lower-doped n-type first pillars 221. As is also shown in FIG. 3D, the lower-doped n-type first pillars 221 may extend upwardly to the lower surfaces of the respective p-wells 230, the higher-doped p-type second pillars 222 may extend upwardly into the p-wells 230 and/or the third higher-doped pillars 223 may extend upwardly to the upper surface of the semiconductor layer structure 250.

The portion of each higher-doped p-type second pillar 222 that horizontally overlaps an adjacent composite n-type pillar 224 may be quasi-charge balanced with the horizontally overlapping portion of the composite n-type pillar 224. As used herein, two elements of a semiconductor device are considered to “horizontally overlap” if an axis that is parallel to the major surfaces of the semiconductor layer structure of the semiconductor device intersects both elements. Herein, laterally adjacent n-type and p-type regions are quasi-charge balanced if the number of charges in the two regions are within 20% of each other. Typically, the number of charges in each higher-doped p-type second pillar 222 may be within 10% or within 5% or even within 2% of the number of charges in each composite n-type pillar 224 that horizontally overlaps the higher-doped p-type second pillar 222.

The semiconductor layer structure 250 may be formed, for example, by first growing a thick silicon carbide layer on the n-type semiconductor substrate 210 by epitaxial growth. A lower portion of the epitaxially grown thick silicon carbide layer will correspond to a drift region 220 of the semiconductor layer structure 250 and may be grown as a lightly-doped n-type silicon carbide region. The p-wells 230 may be formed by implanting p-type dopant ions into an upper portion of the thick silicon carbide layer. The higher-doped p-type second pillars 222, the higher-doped n-type third pillars 223, the p-type well contact regions 238 and the source regions 240 are also formed via ion implantation, typically in separate ion implantation steps. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth. In some embodiments, the implantation may be performed at different temperatures such as, for example, temperatures of 75° C. or more.

Still referring to FIG. 3D, a plurality of gate dielectric layers 260 are formed on the upper surface of the semiconductor layer structure 250. The gate dielectric layers 260 may or may not be connected to each other along the periphery of power MOSFET 200. The gate dielectric layers 260 may comprise, for example, silicon oxide layers, although other insulating materials may be used. A plurality of gate electrodes 270 are formed on the respective gate dielectric layers 260 opposite the semiconductor layer structure 250. The gate electrodes 270 may comprise, for example, a conductive material such as polysilicon, a silicide or a metal. A plurality of intermetal dielectric layers 262 may cover the respective gate electrodes 270. The intermetal dielectric layers 262 may comprise, for example, silicon oxide. The gate dielectric layers 260, the gate electrodes 270 and the intermetal dielectric layers 262 each extend as stripes of material into the page in the view of FIG. 3D.

As best shown in FIG. 3D, the upper surface of the semiconductor layer structure 250 is exposed in between adjacent intermetal dielectric patterns 262. Upper surfaces of the source regions 240 and the p-type well contact regions 238 are thus exposed in between the intermetal dielectric patterns 262. A source metallization layer 280 is formed over the upper surface of the device so that the source metallization layer 280 makes electrical contact to the n-type source regions 240 and the p-type well contact regions 238 while being electrically insulated from the gate electrodes 270 by adjacent intermetal dielectric patterns 262. The source metallization layer 280 may comprise, for example, metals such as nickel, titanium, tungsten and/or aluminum, and/or alloys and/or thin layered stacks of these and/or similar materials. The drain contact 206 is formed on the lower surface of the substrate 210. The drain contact 206 may comprise, for example, the same or similar materials to the source metallization layer 280, and may form an ohmic contact to the silicon carbide substrate 210.

During on-state operation, a voltage that exceeds a so-called “threshold voltage” for power MOSFET 200 is applied to the gate contact pad 202 and passes to the gate electrodes 270. This voltage depletes the carriers in the p-type channel regions 232 that are positioned directly below the gate electrodes 270 (with the gate oxide layers 260 interposed therebetween), thereby allowing current to flow from the source terminal 204, through the source metallization layer 280 and into the source regions 240, through the depleted channel regions 232 to the upper portions of the higher-doped n-type pillars 223 (which serve as JFET regions), and then through the super-junction drift region 220 and substrate 210 to the drain contact 206. The bold arrow in FIG. 3D illustrates one of the on-state current paths.

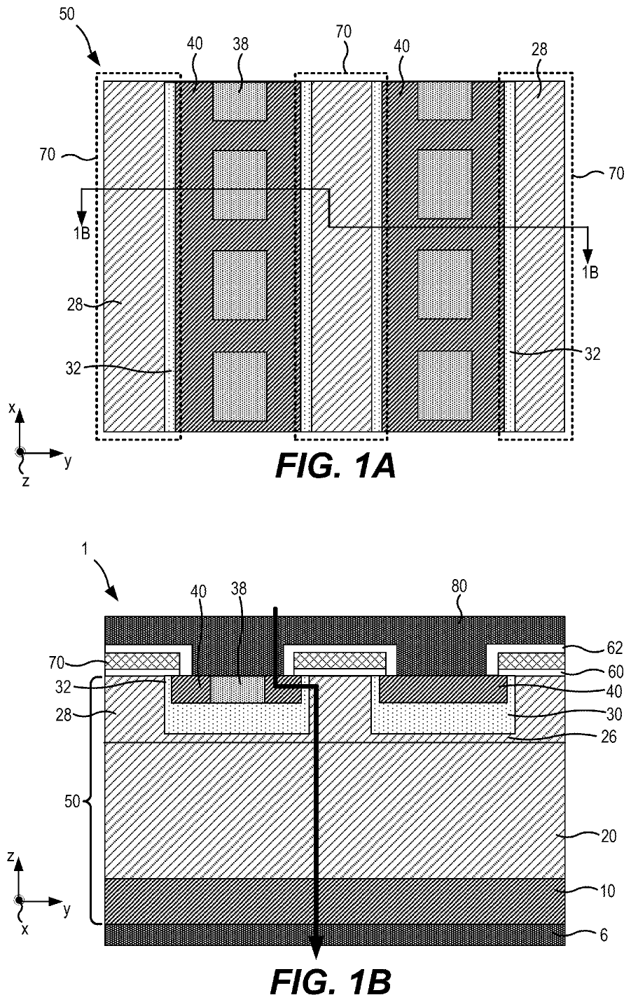

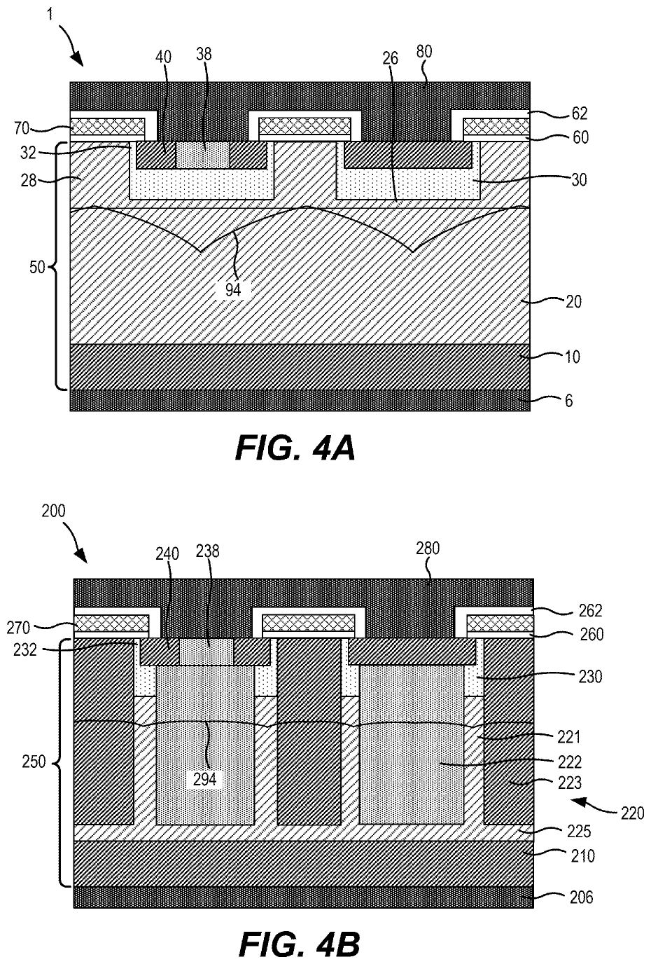

FIG. 4A corresponds to the cross-sectional view of FIG. 1B of conventional power MOSFET 1 with a line 94 added that illustrates the portion an electric field that is formed in the drift region 20 during reverse blocking operation that has a value that exceeds a first (arbitrary) level. As is well understood in the art, during reverse blocking operation strong electric fields extend upwardly from the drain contact 6, with the electric field levels in the drift region 20 being the strongest adjacent the drain contact 6 and gradually weakening as they extend farther upwardly. Thus, in FIG. 4A, the portion of the drift region 20 below the line 94 is the portion in which the electric field will exceed the first level. The p-type well regions 30 tend to block the electric fields, and hence the electric field formed in each unit cell of power MOSFET 1 will have a generally triangular shape with the peak electric field occurring in the middle of each JFET region 28, as shown in FIG. 4A.

FIG. 4B corresponds to the cross-sectional view of FIG. 3D of power MOSFET 200 with a line 294 added that illustrates the portion the electric field that is formed in the drift region 220 that has a value that exceeds a first (arbitrary) level during reverse blocking operation. As shown in FIG. 4B, since the vertically-extending p-n junctions formed by the super junction structure in the drift region 220 are laterally depleted during reverse blocking operation, the electric fields formed in each unit cell of power MOSFET 200 will have a generally rectangular shape, meaning that the electric fields spread better laterally in power MOSFET 200. As a result, the electric field levels adjacent the gate dielectric layers 260 may be lower (for a given blocking voltage), which acts to reduce leakage currents and also results in less stress/damage to the gate dielectric layers 260. Of course, as the doping concentration of the drift region 220 is increased, the electric field values also increase, but the net effect is that power MOSFET 200 may be designed to (1) block the same amount of voltage as power MOSFET 1 while exhibiting a lower on-state resistance, (2) block larger voltages than power MOSFET 1 while exhibiting the same on-state resistance, or (3) a combination of (1) and (2) above.

Referring again to FIGS. 3C-3D, pursuant to some embodiments of the present invention, power semiconductor devices are provided that include a semiconductor layer structure 250 that comprises a drift region 220, a plurality of well regions 230 having a second conductivity type on the drift region 220, and a plurality of source regions 240 having a first conductivity type on the well regions 230. The drift region 220 includes a plurality of first pillars 221 that have the first conductivity type and a first doping concentration, a plurality of second pillars 222 that have the second conductivity type and a second doping concentration, and a plurality of third pillars 223 that have the first conductivity type and a third doping concentration, where the second and third doping concentrations exceed the first doping concentration (e.g., by at least a factor of five), and the first, second and third pillars 221-223 form a super junction structure in the drift region 220. In other specific embodiments, the second and third doping concentrations may exceed the first doping concentration by at least a factor of three or by at least a factor eight. For example, in some specific embodiments, the second and third doping concentrations may exceed the first doping concentration by between a factor of three and a factor of fifteen.

A height of each of first, second and third pillars 221-223 may be at least two microns in example embodiments. Each first pillar 221 contacts a respective one of the second pillars 222 and a respective one of the third pillars 223. Each second pillar 222 is in between and contacts first and second first pillars 221 of a respective pair of the first pillars 221. Each third pillar 223 is in between and contacts first and second first pillars 221 of a respective pair of the first pillars 221. The first pillars 221 extend upwardly from a base portion 225 of the drift region 220, and the base portion 225 of the drift region 220 has the first conductivity type and the first doping concentration. Each second pillar 222 may vertically overlap a respective one (or more) of the source regions 240, and each first pillar 221 may vertically overlap a respective one of the source regions 240.

A lower surface of each second pillar 222 may be a first distance above a lower surface of the drift region 220 and a lower surface of each third pillar 223 may be a second distance above the lower surface of the drift region 220. In some embodiments, the first distance may exceed the second distance. In some embodiments, each third pillar 223 may extend upwardly to an upper surface of the semiconductor layer structure 250. In some embodiments, each first pillar 221 may extend upwardly to a bottom surface of one of the well regions 230.

Still referring to FIGS. 3C-3D, pursuant to further embodiments of the present invention, power semiconductor devices are provided that include a semiconductor layer structure 250 that comprises a drift region 220 and first and second well regions 230 having the second conductivity type on the drift region 220. The drift region 220 includes first and second lower-doped first pillars 221 that have a first conductivity type, first and second higher-doped second pillars 222 that have a second conductivity type, and a higher-doped third pillar 223 that has the first conductivity type. A gate dielectric layer 260 is provided on an upper surface of the semiconductor layer structure 250 and contacts upper surfaces of the first and second well regions 230. The higher-doped third pillar 223 is in between the first and second well regions 230 and is in between and contacting the first and second lower-doped first pillars 221. The semiconductor device further comprises a gate electrode 270 that has a longitudinal axis that extends in a first direction, where the gate electrode 270 is not recessed within the semiconductor layer structure 250. The first and second lower-doped first pillars 221, the first and second higher-doped second pillars 222 and the higher-doped third pillar 223 may also each have respective longitudinal axes that extend in the first direction.

Still referring to FIGS. 3C-3D, pursuant to additional embodiments of the present invention, power semiconductor devices are provided that include a semiconductor layer structure 250 that comprises a drift region 220, a plurality of well regions 230 having a second conductivity type on the drift region 220, and a plurality of source regions 240 having a first conductivity type on the well regions 230. The drift region 220 includes a pair of first pillars 221 that have the first conductivity type and a first doping concentration, a second pillar 222 that has the second conductivity type and a second doping concentration, and a third pillar 223 that has the first conductivity type and a third doping concentration, where the second and third doping concentrations exceed the first doping concentration. The third pillar 223 is in between and contacting the two first pillars 221 in the pair of first pillars so that the pair of first pillars 221 and the third pillar 223 form a composite pillar 224. Moreover, a first portion of the second pillar 222 that horizontally overlaps a first portion of the composite pillar 224 is charge balanced with the first portion of the composite pillar 224.

In the embodiment of FIGS. 3A-3D, the semiconductor device 200 is an n-type MOSFET that includes a substrate 210 drift region 225, source regions 240 and first and third pillars 221, 223 that are n-type regions, along with well regions 230, well contact regions 238 and second pillars 222 that are p-type regions. It will be appreciated that the conductivity type of each of these regions may be reversed in other embodiments to provide a p-type MOSFET.

It will also be appreciated that in other embodiments all of the regions could have the same conductivity types shown in FIGS. 3C-3D, except that the first pillars 221 could be changed to be p-type pillars instead of the n-type pillars shown in FIG. 3D. Such a device could be formed, for example, by epitaxially growing the bottom portion 225 of the drift region 220 to be an n-type region, and then growing the portion of the drift region 220 that has the super junction structure as a p-type region. The p-type second pillars 222 and the n-type third pillars 223 are then formed in the drift region 220, thereby creating the p-type first pillars 221. In such an embodiment, the super junction structure is designed so that the p-type first and second pillars 221, 222 are charge balanced with the n-type third pillars 223.

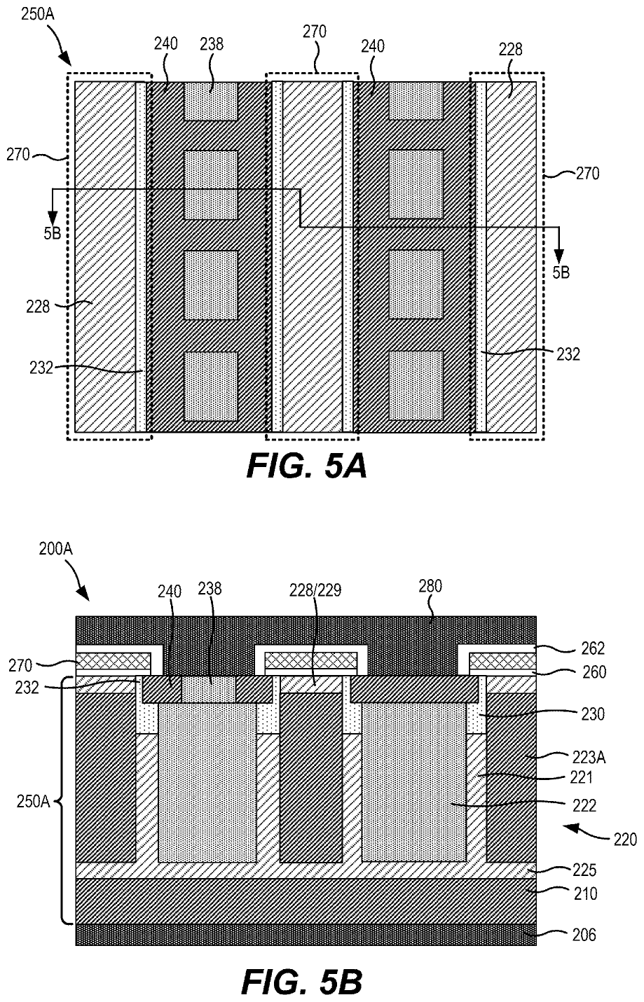

It will be appreciated that a wide variety of changes may be made to power MOSFET 200 without departing from the teachings of the present invention. For example, FIGS. 5A-5B are a plan view and a cross-sectional view, respectively, of a power MOSFET 200A that is a modified version of power MOSFET 200, where the views of FIGS. 5A-5B correspond to FIGS. 3C-3D, respectively.

As can be seen by comparing FIGS. 5A-5B to FIGS. 3C-3D, power MOSFET 200A differs from power MOSFET 200 solely in that the heavily-doped third pillars 223A that are included in power MOSFET 200A do not extend to the upper surface of semiconductor layer structure 250A. Thus, the upper portions 229 of the JFET regions 228 that are directly underneath the respective gate dielectric layers 260 are more lightly doped n-type than the third pillars 223A. For example, the upper portion 229 of each JFET region 228 may be doped n-type at the same level as the lower portion 225 of the drift region 220 or may be doped more heavily n-type than the lower portion 225 of the drift region 220 but doped to a concentration that is less than the doping concentration of the heavily-doped third pillars 223A by at least a factor of three. As a result, the portion 229 of each JFET region 228 of power MOSFET 200A that is directly underneath the gate oxide layers 260 may have a lower n-type doping concentration than the highly-doped n-type third pillars 223A. Because of the lower doping concentration, the electric fields directly underneath the gate oxide layers 260 of power MOSFET 200A may be reduced as compared to the electric fields directly underneath the gate oxide layers 260 of power MOSFET 200, although this benefit is achieved at the cost of an increase in the on-state resistance.

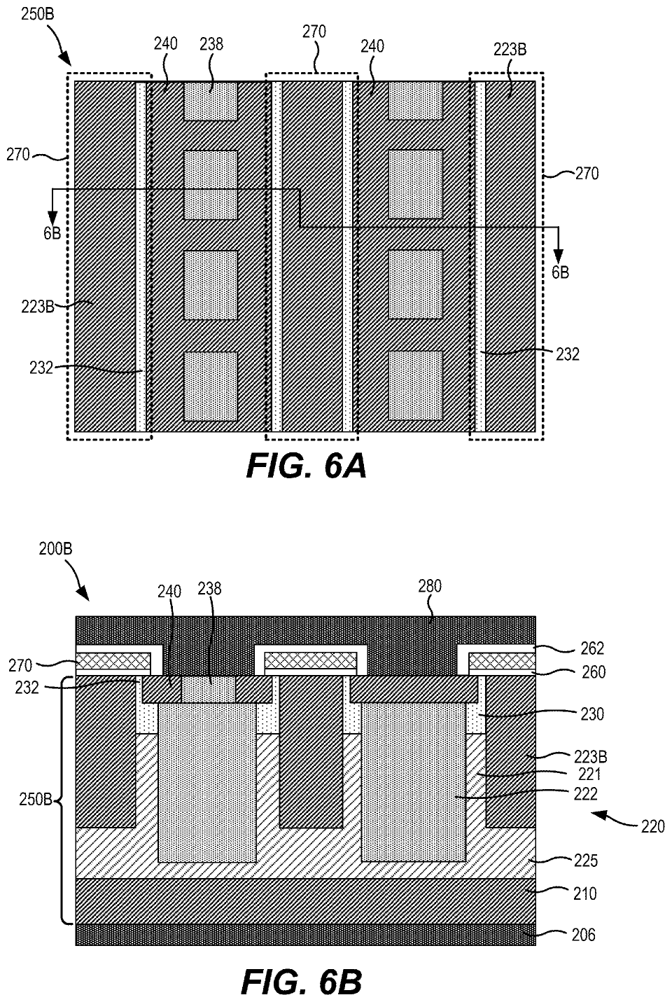

FIGS. 6A and 6B are a schematic plan view and a cross-sectional view that correspond to FIGS. 3C and 3D, respectively, that illustrate a power MOSFET 200B that is another modified version of the power MOSFET 200 of FIGS. 3A-3D. As can be seen by comparing FIGS. 6A-6B to FIGS. 3C-3D, power MOSFET 200B differs from power MOSFET 200 solely in that the highly-doped third pillars 223 that are included in power MOSFET 200B do not extend as deeply into the semiconductor layer structure 250B as do the highly-doped third pillars 223 of power MOSFET 200, and thus also do not extend as deeply into the semiconductor layer structure 250B as do the highly-doped second pillars 222. As a result, less of the drift region 220 of power MOSFET 200B will act as a super junction structure than is the case with power MOSFET 200. It will be appreciated that in other embodiments (not shown), the highly-doped third pillars 223 may instead extend to the same depth into the semiconductor layer structure 250 than the highly-doped second pillars 222.

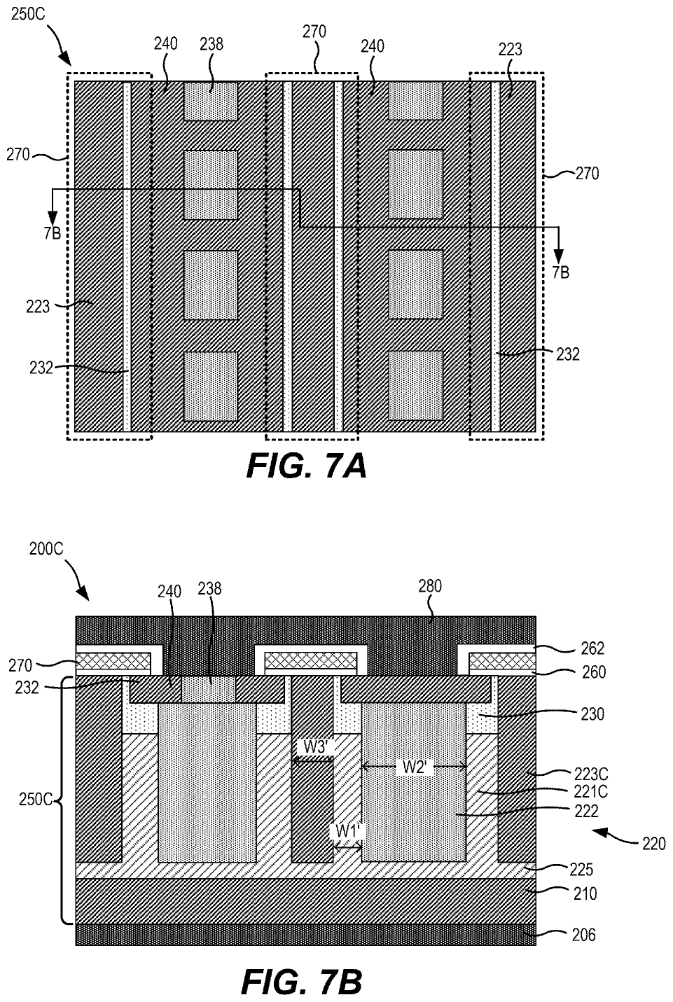

FIGS. 7A and 7B are a schematic plan view and a cross-sectional view that correspond to FIGS. 3C and 3D, respectively, that illustrate a power MOSFET 200C that is yet another modified version of the power MOSFET 200 of FIGS. 3A-3D. As can be seen by comparing FIGS. 7A-7B to FIGS. 3C-3D, power MOSFET 200C differs from power MOSFET 200 solely in that the transverse width W3′ of each highly-doped third pillar 223C that is included in power MOSFET 200C is decreased as compared to the transverse width W3 of each highly-doped third pillar 223 of power MOSFET 200, and the transverse width W1′ of the each lower-doped first pillar 221C that is included in power MOSFET 200C is increased as compared to the transverse width W1 of each lower-doped first pillar 221 of power MOSFET 200. The doping concentrations of the highly-doped third pillars 223C and/or the lower-doped first pillars 221C may be adjusted to ensure that charge balance is maintained with respect to the highly-doped second pillars 222. It will also be appreciated that the transverse width W2′ of each highly-doped second pillar 222 of power MOSFET 200C may be adjusted in other embodiments (increased or decreased) as compared to the transverse width W2 of each highly-doped second pillar 222 of power MOSFET 200.

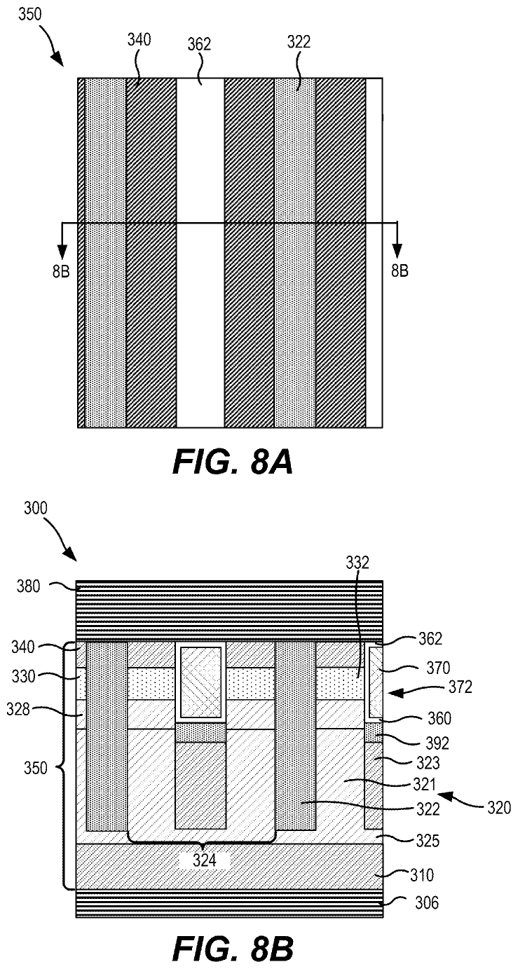

FIG. 8A is a schematic plan view of a portion of a top surface of a semiconductor layer structure 350 of a power MOSFET 300 according to further embodiments of the present invention. FIG. 8B is a schematic cross-sectional view taken along the line 8B-8B of FIG. 8A with portions of the upper metallization and dielectric layers of the power MOSFET 300 added for context.

Power MOSFET 300 is similar to power MOSFET 200 of FIGS. 3A-3D, but has gate electrodes that are formed within trenches 372 in the semiconductor layer structure 350 instead of having the planar gate electrode design of power MOSFET 200. In other words, power MOSFET 300 is a gate trench version of power MOSFET 200. Given the similarities between power MOSFETs 200 and 300, the description of power MOSFET 300 herein will focus on the differences between power MOSFETs 200 and 300.

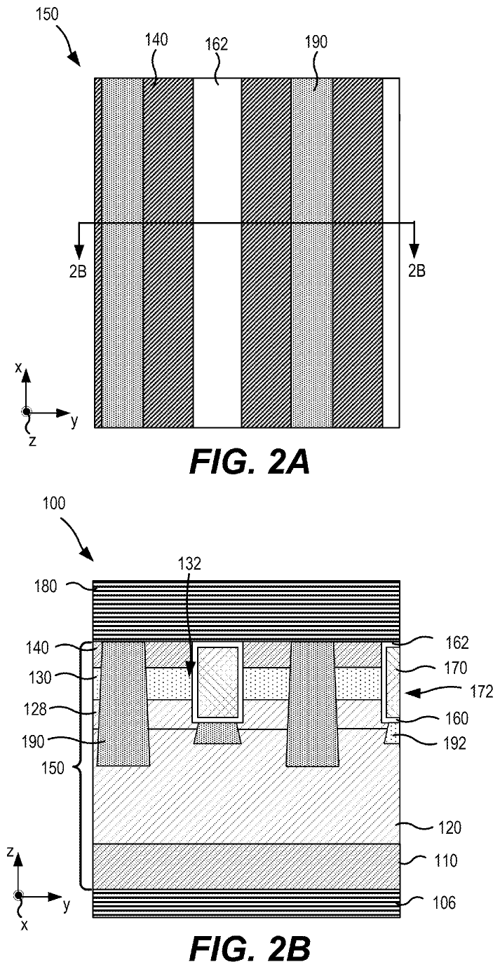

As discussed above with reference to FIGS. 2A-2B, trench gate power MOSFETs such as power MOSFET 100 are known in the art. Power MOSFET 300 primarily differs from conventional trench gate power MOSFET 100 in that power MOSFET 300 has a super junction style drift region 320 that includes a modified super junction structure that has a plurality of lower-doped n-type first pillars 321, a plurality of higher-doped p-type second pillars 322, and a plurality of higher-doped n-type third pillars 323. A pair of lower-doped n-type first pillars 321 are formed on either side of each higher-doped n-type third pillar 323. Each pair of lower-doped n-type first pillars 321 and the higher-doped n-type third pillar 223 therebetween form a respective composite n-type pillar 324. A pair of higher-doped p-type second pillars 322 are provided on either side of each composite n-type pillar 324. Consequently, the drift region 320 includes alternating p-type second pillars 322 and composite n-type pillars 324. The pillars 321-324 do not extend downwardly all of the way to the lower surface of the drift region 320 so that the lower portion of the drift region 320 is a continuous lightly-doped n-type region 325. In some embodiments, the lower portion 325 of the drift region 320 may be more highly doped n-type than the first pillars 321. The higher-doped p-type second pillars 322 replace the support shields 190 included in power MOSFET 100.

As in conventional power MOSFET 100, power MOSFET 300 includes trench shielding regions 392 that extend longitudinally underneath the respective gate trenches 372. Each trench shielding region 392 may be a relatively heavily-doped p-type region (e.g., doped to a concentration between 1×10¹⁷ cm⁻³ and 5×10¹⁹ cm⁻³). The third higher-doped n-type pillars 323 are formed underneath the respective trench shielding regions 392 and may extend the full length of the trench shielding regions 392 and the gate trenches 372. The higher-doped p-type second pillars 322 may extend upwardly into (and potentially through) the p-wells 330, and hence the higher-doped p-type second pillars 322 may have larger thicknesses (depths) than the higher-doped n-type third pillars 323. The portions of the higher-doped p-type second pillars 322 that extend adjacent (i.e., horizontally overlapping) the composite n-type pillars 324 may be quasi-charge balanced with the composite n-type pillars 324 to form a super junction structure in the drift region 320.

As best seen in FIG. 8B, the primary differences between power MOSFETs 200 and 300 are that (1) the gate dielectric layers 360 and gate electrodes 370 of power MOSFET 300 are formed in trenches 372 in the semiconductor layer structure 350 as opposed to being formed on top of the semiconductor layer structure as is the case with power MOSFET 200, (2) the source region 340 extends over the channel regions 332 in power MOSFET 300, (3) power MOSFET 300 includes JFET regions 328 underneath the p-wells 330, and (4) a p-type trench shielding region 392 is provided in MOSFET 300 in between the bottom of each gate trench and a top surface of a respective one of the higher-doped n-type third pillars 323.

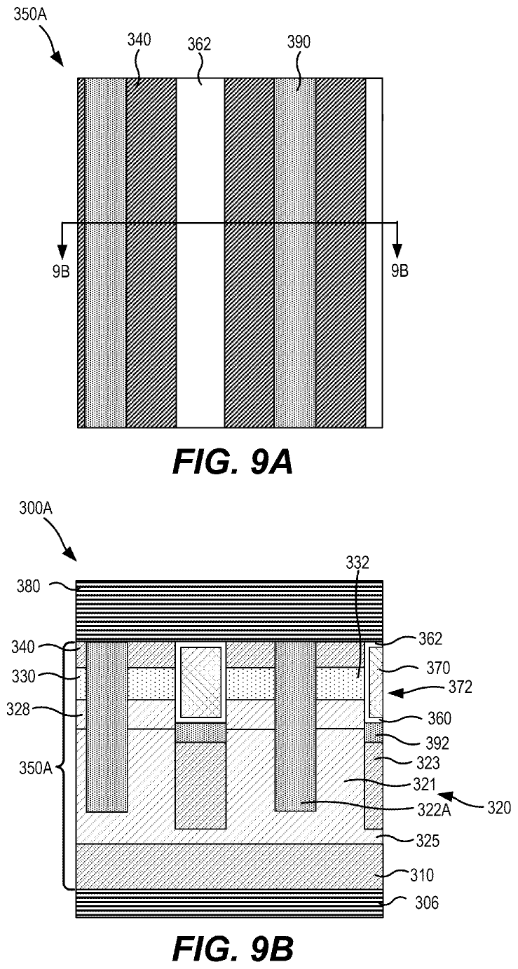

FIGS. 9A and 9B are a schematic plan view and a cross-sectional view that correspond to FIGS. 8A-8B, respectively, that illustrate a power MOSFET 300A that is a modified version of the power MOSFET 300 of FIGS. 8A-8B. As can be seen by comparing FIGS. 9A-9B to FIGS. 8A-8B, power MOSFET 300A differs from power MOSFET 300 solely in that the highly-doped p-type second pillars 322A that are included in power MOSFET 300A do not extend as deeply into the semiconductor layer structure 350A as do the higher-doped p-type second pillars 322 of power MOSFET 300. As a result, less of the drift region 320 of power MOSFET 300A will act as a super junction structure than is the case with power MOSFET 300. It will be appreciated that in other embodiments (not shown), the highly-doped second pillars 323A may instead extend deeper into the semiconductor layer structure 350A than the highly-doped third pillars 323.

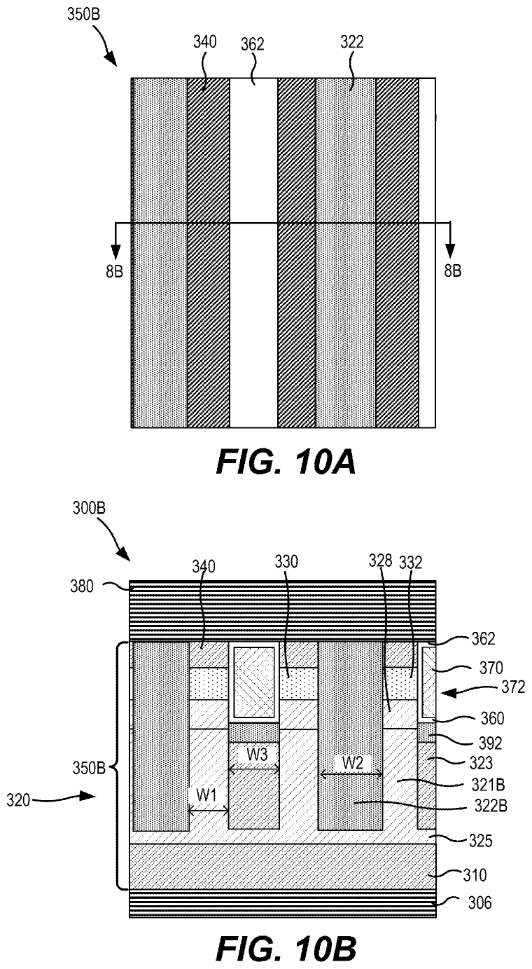

FIGS. 10A-10B are a schematic plan view and a cross-sectional view that correspond to FIGS. 8A-8B, respectively, that illustrate a power MOSFET 300B that is another modified version of the power MOSFET 300 of FIGS. 8A-8B. As can be seen by comparing FIGS. 10A-10B to FIGS. 8A-8B, power MOSFET 300B differs from power MOSFET 300 solely in that the transverse width W3 of each highly-doped second pillar 322B that is included in power MOSFET 300B is increased as compared to the transverse width of each highly-doped second pillar 322 of power MOSFET 300, and the transverse width W1 of the each lower-doped first pillar 321B that is included in power MOSFET 300B is decreased as compared to the transverse width of each lower-doped first pillar 321 of power MOSFET 300. The doping concentrations of the first, second and/or third pillars 321B, 322B, 323 may be adjusted to ensure that charge balance is maintained in the super junction style drift region 320. It will also be appreciated that the transverse width W2 of each highly-doped second pillar 322 of power MOSFET 300B may be decreased in other embodiments as compared to the transverse width of each highly-doped second pillar 322 of power MOSFET 300.

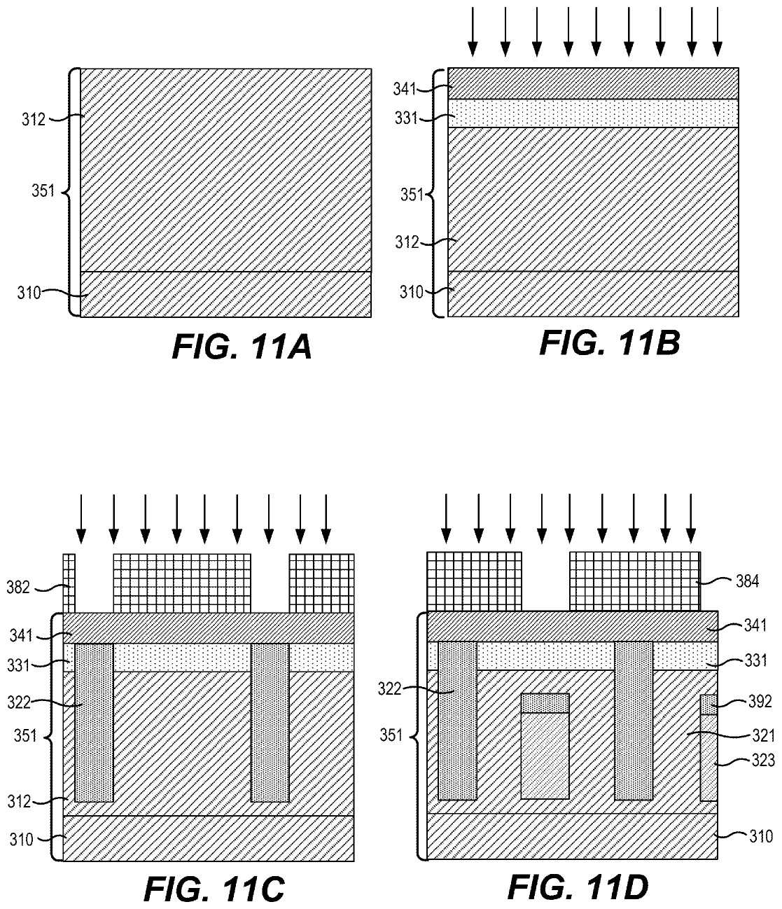

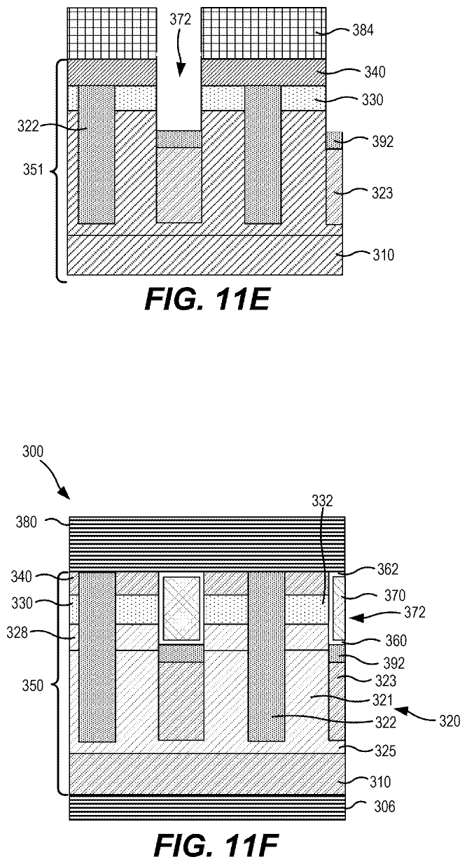

FIGS. 11A-11F are schematic cross-sectional views illustrating a method of fabricating the power MOSFET 300 of FIGS. 8A-8B.

As shown in FIG. 11A, a thick semiconductor layer 312 is formed on a highly-doped n-type semiconductor substrate 310 via, for example, epitaxial growth. The thick semiconductor layer 312 may be a lightly-doped n-type silicon carbide layer (as shown). The semiconductor substrate 310 and the thick semiconductor layer 312 together form a preliminary semiconductor layer structure 351.

Referring to FIG. 11B, a first ion implantation process is performed to implant p-type dopants into an upper portion of the thick semiconductor layer 312 in order to form a p-well layer 331. The first ion implantation process may be a “blanket” process that implants the p-type dopant ions throughout the entire active region of power MOSFET 300. Next, a second ion implantation process is performed to implant n-type dopants into an upper portion of the thick semiconductor layer 312 in order to form a source layer 341. The second ion implantation process may also be a blanket process that implants the n-type dopant ions throughout the entire active region of power MOSFET 300. The second ion implantation process may be performed at lower ion implantation energies so only the region labelled 341 is implanted. The first ion implantation process may be a buried ion implantation process that primarily implants the p-type dopant ions into the region labelled 331 in FIG. 11B, or may also implant the p-type dopant ions into the region labelled 341 in FIG. 11B (since the second ion implantation process has a much heavier does, and hence the n-type dopants overwhelm any p-type dopants that are implanted into the region labelled 341 in FIG. 11B). It will be appreciated that the order of the first and second ion implantation processes may be reversed. While not shown in FIG. 11B, ion implantation masks may be used during the first and second ion implantation processes to shield certain sections of, for example, the inactive region during the first and second ion implantation processes.

Referring to FIG. 11C, a first ion implantation mask 382 is formed on the upper surface of the preliminary semiconductor layer structure 351. The first ion implantation mask 382 may be an oxide mask that is patterned using standard photolithography techniques. The first ion implantation mask 382 may comprise a plurality of spaced apart stripes of mask material in the active region of the device. A longitudinal axis of each stripe of mask material may extend in the same direction as the longitudinal axes of the gate electrodes 370 that are formed in later processing steps. Next, a third ion implantation process is used to implant p-type dopants into portions of the preliminary semiconductor layer structure 351 that are exposed by the first ion implantation mask 382 to form a plurality of higher-doped p-type second pillars 322 in the preliminary semiconductor layer structure 351. The higher-doped p-type second pillars 322 may be moderately or heavily doped p-type. The third ion implantation process may be a high energy, high dosage ion implantation process. The first ion implantation mask 382 may then be removed.

The third ion implantation process may be a channeled ion implantation process. As discussed, for example, in U.S. Pat. No. 11,075,264, the entire content of which is incorporated herein by reference, channeled ion implantation refers to ion implantation where the dopant ions are implanted along certain crystallographic axes in the semiconductor layer structure where channels are formed, where a channel refers to an area where atoms are not present when viewed along the crystallographic axis. When dopant ions are implanted along the crystallographic axes that have channels, the dopant ions that are implanted into the channel areas may travel much farther into the semiconductor layer structure due to the absence of atoms, allowing the dopants to be implanted at deeper depths while using lower implantation energies (which advantageously reduces damage to the semiconductor material from the implantation and which also reduces scattering of the dopant ions to unintended locations in the crystal lattice). As explained in U.S. Pat. No. 11,075,264, there are crystallographic axes which support channeled ion implantation. When channeled ion implantation is used, not only may the dopant ions be implanted to deeper depths using less implantation energy, but the reduced scattering allows the implanted regions to have more vertical sidewalls than is possible when standard ion implantation techniques are used. Thus, the use of channeled ion implantation techniques may be well suited for forming a super junction style drift region having adjacent pillars of n-type and p-type material.

In 4H silicon carbide based devices, there are three sets of crystallographic axes which are amenable to channeled ion implantation, namely (1) the <0001> crystallographic axis, (2) the <11−23> crystallographic axis (and the symmetrically equivalent <−1−123>, <1−213>, <−12−13>, <Feb. 1, 2013> and <−2113> crystallographic axes) and (3) the <11−20> crystallographic axis. The channeled ion implantation step may be performed along any of these crystallographic axes.

Referring to FIG. 11D, a second ion implantation mask 384 may be formed on the upper surface of the preliminary semiconductor layer structure 351. The second ion implantation mask 384 may also be an oxide mask that is patterned using standard photolithography techniques. The second ion implantation mask 384 may comprise a plurality of spaced apart stripes of mask material in the active region of the device. A longitudinal axis of each stripe of mask material may extend in the same direction as the longitudinal axes of the gate electrodes 370 that are formed in later processing steps. Next, a fourth ion implantation process is used to form a plurality of higher-doped n-type third pillars 323 in the preliminary semiconductor layer structure 351. Each higher-doped n-type third pillar 323 may be a buried pillar that is formed below a respective one of the p-wells 330. The fourth ion implantation process may be a high energy channeled ion implantation process. Formation of the higher-doped n-type third pillars 323 acts to define a plurality of lower-doped n-type first pillars 321 in the drift region 320, where the lower-doped n-type first pillars 321 are the portions of the drift region between the higher-doped p-type second pillars 322 and the higher-doped n-type third pillars 323.

Still referring to FIG. 11D, a fifth ion implantation process is performed using the second ion implantation mask 384 as an ion implantation mask to implant p-type dopants into the preliminary semiconductor layer structure 351 to form a plurality of trench shielding regions 392 in the preliminary semiconductor layer structure 351. As shown, the trench shielding regions 392 may be formed as buried implanted regions. Each trench shielding region 392 may be formed above a respective one of the higher-doped n-type third pillars 323. It will be appreciated that the order of the fourth and fifth ion implantation processes may be reversed.

Referring to FIG. 11E, an etching process may be performed on the preliminary semiconductor layer structure 351 using the second ion implantation mask 384 as an etching mask to form a plurality of gate trenches 372 in the preliminary semiconductor layer structure 351. The second ion implantation mask 384 may then be removed. It will be appreciated that in other embodiments the gate trenches 372 may be formed before the fourth and fifth ion implantation processes are performed so that the fourth and fifth ion implantation processes may be performed using lower energy implantation processes.

Referring to FIG. 11F, thereafter, gate dielectric layers 360, gate electrodes 370, intermetal dielectric layers 362, and source and drain metallization layers 380, 306 may be formed to complete the power MOSFET 300.

The embodiments of the present invention discussed above may align the super junction structures in the drift region with the unit cell structure of the power semiconductor device that is provided above the drift region. For example, in power MOSFET 200 of FIGS. 3A-3D, the higher-doped p-type pillars 222 may be aligned with the p-wells 230 and the higher-doped n-type pillars 223 may be aligned underneath the gate electrodes 270. It will be appreciated, however, that the super junction structures in the drift region and the unit cell structure of the power semiconductor device need not be aligned.

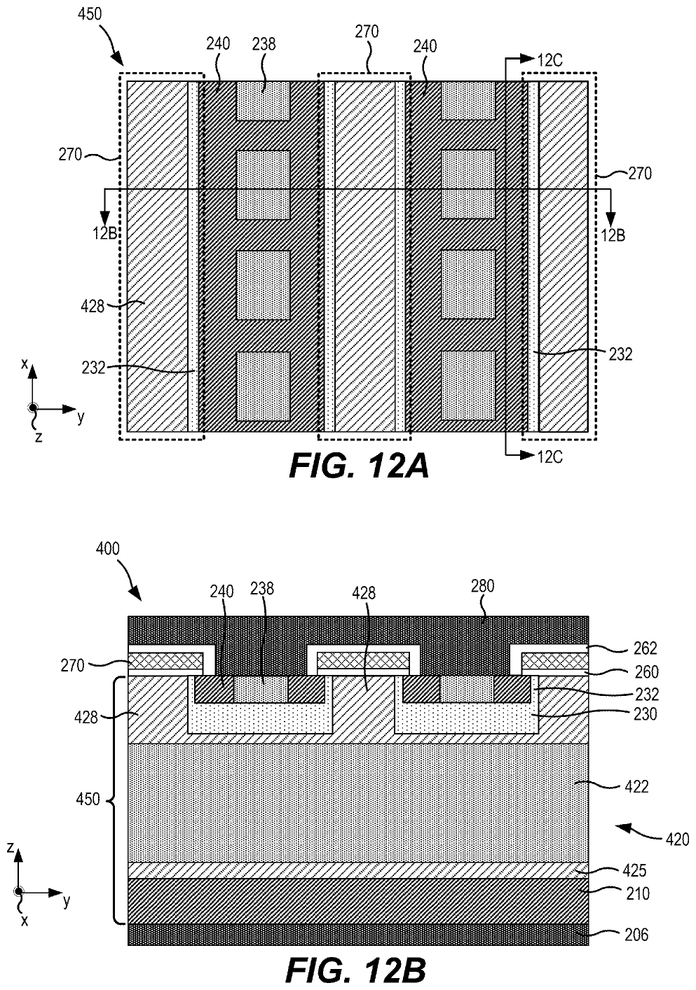

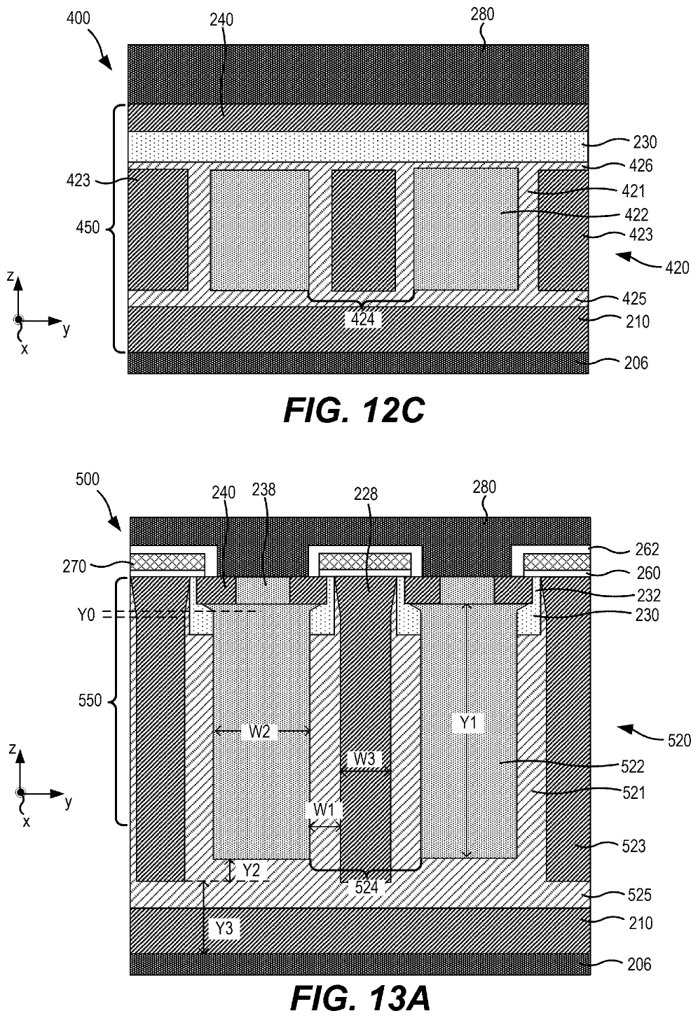

For example, FIGS. 12A-12C illustrate a power MOSFET 400 according to further embodiments of the present invention that has a drift region 420 with a super junction structure that is not aligned with the cell structure of the device. Power MOSFET 400 may appear identical to power MOSFET 200 when viewed in plan view. Consequently, FIG. 3A accurately depicts power MOSFET 400 as well as power MOSFET 200. FIG. 12A is a schematic top view of the upper surface of a semiconductor layer structure 450 of MOSFET 400 that corresponds to the box labelled A in FIG. 3B. The dotted boxes in FIG. 12A illustrate the locations of the gate electrodes 270. FIGS. 12B and 12C are cross-sectional views taken along lines 12B-12B and 12C-12C, respectively, of FIG. 12A, where FIGS. 12B and 12C illustrate various of the metal and dielectric layers that are formed on the upper surface of the semiconductor layer structure 450 that are omitted from the view of FIG. 12A.

The primary differences between power MOSFET 200 of FIGS. 3A-3D and power MOSFET 400 of FIGS. 12A-12C are that (1) the super junction structure that is formed in the drift region 420 of power MOSFET 400 is rotated 90° in the x-y plane with respect to the super junction structure that is formed in the drift region 220 of power MOSFET 200 and (2) the super junction structure that is formed in the drift region 420 of power MOSFET 400 does not extend into the p-wells and the JFET regions that are formed in the upper portion of the drift region 420.

Referring first to FIGS. 3C and 12A, it can be seen that the upper surface of the semiconductor layer structure 450 of power MOSFET 400 (shown in FIG. 12A) is almost identical to the upper surface of the semiconductor layer structure 250 of power MOSFET 200 (shown in FIG. 3C), with the only difference being that in power MOSFET 400 the higher-doped n-type pillars 423 that are included in the super junction structure of power MOSFET 400 do not extend to the upper surface of the semiconductor layer structure 450 and hence are not visible in FIG. 12A (instead the JFET region 428 is visible), whereas the higher-doped n-type pillars 223 that are included in the super junction structure of power MOSFET 200 are visible in FIG. 3C. Thus, further description of FIG. 12A will be omitted.

Referring next to FIGS. 12B and 3D, it can be seen that upper portion of cross-section of power MOSFET 400 taken along line 12B-12B of FIG. 12A may be similar to the upper portion of cross-section of power MOSFET 200 taken along line 3C-3C of FIG. 3C, but the super junction structure that is included in the drift region 420 of power MOSFET 400 does not extend into the unit cell structure of the device, whereas the higher-doped p-type pillars 222 and the higher-doped n-type pillars 223 of the super junction structure included in the drift region 220 of power MOSFET 200 extend into the unit cell structure in power MOSFET 200 (in particular, the higher-doped p-type pillars 222 extend into the p-wells 230 and the higher-doped n-type pillars 223 extend into the JFET regions 228). In addition, since in power MOSFET 400 the super junction structure is rotated 90° in the x-y plane with respect to the super junction structure that is formed in the drift region 220 of power MOSFET 200, in the view of FIG. 12B the only portion of the super junction structure that is visible is one of the higher-doped n-type pillars 423, as the cross-section runs along the longitudinal axis of the pillar 423 and does not cross any other pillars of the super junction structure.

Referring next to FIG. 12C, it can be seen that the super junction structure that is formed in the drift region 420 of power MOSFET 400 includes a plurality of lower-doped n-type pillars 421, a plurality of higher-doped p-type pillars 422 and a plurality of higher-doped n-type pillars 423 that extend in parallel to each other. Similar to power MOSFET 200, the super junction structure includes a plurality of composite n-type pillars 424, where each composite pillar comprises a higher-doped n-type pillar 423 and a pair of lower-doped n-type pillars 421. As can be seen the pillars 421, 422, 423 do not extend all the way to the bottom of the drift region 420 (as is also the case for pillars 221, 222, 223 in power MOSFET 200) so that the lower portion 425 of the drift region is a lower-doped n-type region. In addition, since the pillars 421, 422, 423 do not extend all the way to the top of the drift region 420 in power MOSFET 400, the upper portion 426 of drift region 420 is also a lower-doped n-type region.

While FIGS. 12A-12C illustrate a power MOSFET in which the super junction structure is rotated 90° in the x-y plane with respect to the super junction structure that is formed in the drift region 220 of power MOSFET 200, it will be appreciated that this is provided merely as an example. In other embodiments, the super junction structure may be rotated any arbitrary amount (e.g., 30°, 45°, 60°, etc.) in the x-y plane with respect to the super junction structure that is formed in the drift region 220 of power MOSFET 200. It will likewise be appreciated that the super junction structure need not have fin-like pillars.

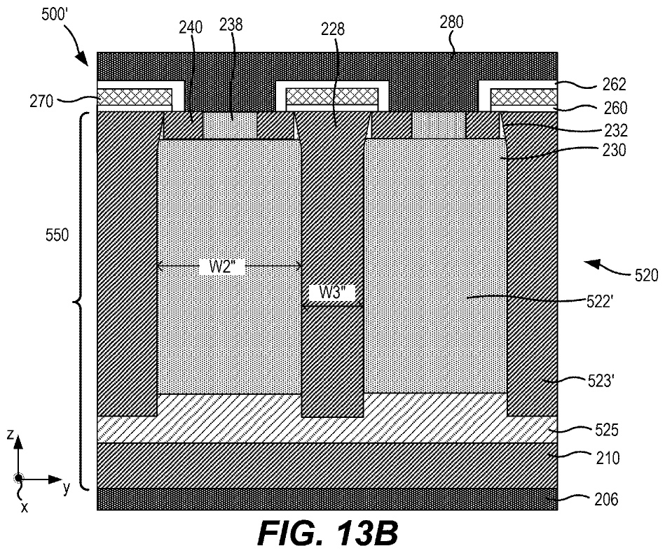

FIG. 13A is a schematic cross-sectional view of a power MOSFET 500 according to further embodiments of the present invention. It will be appreciated that some or all of the features of the semiconductor layer structure 550 of power MOSFET 500 may replace the corresponding features of the semiconductor layer structures of the above-descried embodiments of the present invention. In other words, FIG. 13A shows a series of modifications that may be made to any of the above-descried embodiments of the present invention.

As shown in FIG. 13A, the power MOSFET 500 includes a plurality of unit cell transistors that are (primarily) formed in the upper portion of the device and a drift region 520 that includes a super junction structure. The super junction structure includes a plurality of lower-doped n-type pillars 521, a plurality of higher-doped p-type pillars 522 and a plurality of higher-doped n-type pillars 523, where each of the pillars 521, 522, 523 generally has a fin shape and the pillars 521, 522, 523 extend parallel to each other, as is the case with the super junction structure of power MOSFET 200 of FIGS. 3A-3D. The higher-doped n-type pillars 523 extend deeper into the semiconductor layer structure 550 than do the higher-doped p-type pillars 522. This may be advantageous as it may ensure that the higher-doped p-type pillars 522 are fully depleted during reverse blocking operation.

The super junction structure of power MOSFET 500, however, has a somewhat modified design. For example, the upper portions of the higher-doped p-type pillars 522 and/or the higher-doped n-type pillars 523 may be wider than the lower portion, and may have a funnel shape (in cross-sectional view) where the width gradually decreases with increasing depth. This shape may naturally occur when channeled ion implantation techniques are used to form the pillars 522, 523, and the doping concentration of the wider portion of each pillar 522, 523 may be less than the doping concentration of the lower (narrower) portion of each pillar 522, 523.

As also shown in FIG. 13A, the pillars 521, 522, 523 may be deep pillars that extend a significant distance into the semiconductor layer structure 550. In example embodiments, each pillar may extend in the depth direction for at least 5 microns or at least 10 microns, and may extend as much as 100 microns or more in the depth direction. In some embodiments, one or more of the pillars 521, 522, 523 may extend in the depth direction for at least 40%, at least 50%, at least 60%, at least 70%, at least 80% or at least 90% of the depth of the drift region 520. As discussed above, the higher-doped p-type pillars 522 and/or the higher-doped n-type pillars 523 may be formed using channeled ion implantation techniques to facilitate forming such deep pillars.

As discussed in the above-referenced U.S. Pat. No. 11,075,264, in 4H silicon carbide based devices, there are three sets of crystallographic axes which are amenable to channeled ion implantation, namely (1) the <0001> crystallographic axis, (2) the <11-23> crystallographic axis (and the symmetrically equivalent <−1-123>, <1-213>, <−12-13>, <Feb. 1, 2013> and <−2113> crystallographic axes) and (3) the <11-20> crystallographic axis. In some embodiments of the present invention, the higher-doped p-type pillars 522 may be formed using channeled ion implantation techniques along one of the above three crystallographic axes and the higher-doped n-type pillars 523 may be formed using channeled ion implantation techniques along another (different) one of the above three crystallographic axes.

Similar to power MOSFET 200, the pillars 521, 522, 523 of the super junction structure of power MOSFET 500 do not extend into a lowermost portion 525 of the drift region 520. Moreover, the lowermost portion 525 of the drift region 520 may be higher-doped n-type than the lower-doped n-type pillars 521. For example, the lowermost portion 525 of the drift region 520 may have an n-type doping concentration that is at least 25% higher, or at least 50% higher, or at least 100% higher than the n-type doping concentration of the pillars 521.

In example embodiments, the transverse widths W1, W2, W3 of the respective first pillars 521, second pillars 522 and third pillars 523 may be between 0.01 and 10 microns, although embodiments of the present invention are not limited thereto. The doping concentration of each second pillar 522 multiplied by the width W2 of the second pillar 522 may be equal to the sum of the doping concentration of each third pillar 523 multiplied by the width W3 of the third pillar 523 plus the doping concentration of each first pillar 521 multiplied by the width W1 of the first pillar 521. As discussed above with reference to the embodiment of FIGS. 3A-3D, the second and third pillars 522, 523 have doping concentrations that are higher than the doping concentration of the first pillars 521, and typically much higher (e.g., five to fifteen times or more higher). Given this difference in doping concentration and the fact that each third pillar 523 typically has a width that is smaller than the width W1 of the first pillars 521, the first pillars 521 may have negligible impact on the charge balance of the n-type and p-type regions of the super junction structure in some embodiments. In such cases, the doping concentration of each second pillar 522 multiplied by the width W2 of the second pillar 522 may be approximately equal to the doping concentration of each third pillar 523 multiplied by the width W3 of the third pillar 523. The vertical distance between the bottom of the funnel portions of the second pillars 522 and the bottom of the funnel portions of the third pillars 523 may be between 0.01 and 5 microns. The vertical depth Y1 of the second pillars 522 (starting from the bottom of the funnel portion thereof) may be between 0.01 and 100 micros. The distance Y2 between the bottom of the second pillars 522 and the bottom of the third pillars 523 may be between 0.01 and 50 microns. The distance from the bottom of the third pillars 523 to the bottom of the substrate 210 may be between 0.01 and 100 microns.

It should be noted that in FIG. 13A the super junction structure extends into the unit cell structure (i.e., into the p-wells and/or the JFET regions), whereas in FIGS. 12A-12C the super junction structure does not extend into the p-wells or JFET regions, and instead the super junction structure does not extend as high in the semiconductor layer structure as the drift region such that the uppermost portion of the drift region is a continuous n-type region. It will be appreciated that the embodiments of the invention disclosed herein may have either design.

FIG. 13B is a schematic cross-sectional view of a power MOSFET 500′ according to further embodiments of the present invention that is modified version of the power MOSFET 500 of FIG. 13A. As can be seen by comparing FIGS. 13A and 13B, power MOSFET 500′ differs from power MOSFET 500 in that one or both of the widths W2″ and W3″ of the respective second and third pillars 522′, 523′ are expanded as compared to the widths W2 and W3 of the respective second and third pillars 522, 523 in power MOSFET 500 so that the first pillars 521 are eliminated. As a result, the power MOSFET 500′ has a more conventional super junction structure of alternating n-type and p-type pillars. It will be appreciated that this change may be made to any of the embodiments disclosed herein.

In the above embodiments of the present invention, the power semiconductor device is depicted as a power MOSFET having a “stripe” configuration, which refers to vertical power MOSFETs that have longitudinally-extending well regions, source regions and gate electrodes that extend as stripes of material. It will be appreciated, however, that embodiments of the present invention are not limited thereto. For example, the techniques disclosed herein may be used in power MOSFETs that have a so-call “cell” configuration where the well regions are arranged as spaced apart islands when the semiconductor layer structure is viewed in plan view. MOSFETs having cell configurations may provide higher cell (or MOS channel) packing density than MOSFETs having the more conventional stripe configuration that is discussed above.

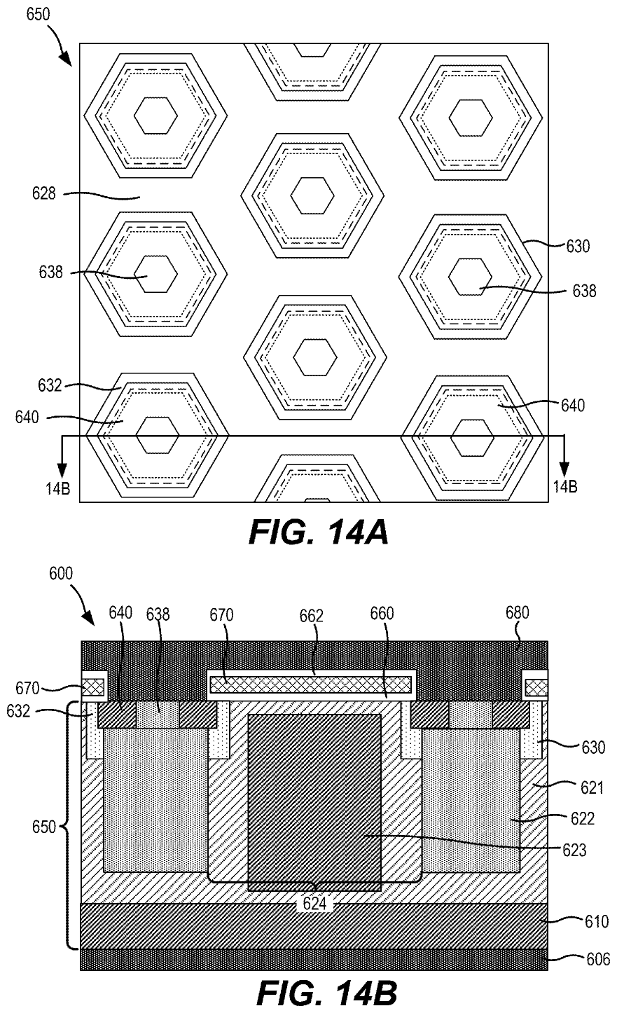

FIGS. 14A-14B schematically illustrate a power MOSFET 600 according to further embodiments of the present invention which has a cell configuration. In particular, FIG. 14A is a schematic top view of the upper surface of a semiconductor layer structure 650 of the power MOSFET 600, and FIG. 14B is a cross-sectional view taken along line 14B-14B of FIG. 14A. FIG. 14B also includes some of the upper metallization and dielectric layers to provide additional context.

Referring to FIG. 14A, it can be seen that a plurality of p-wells 630 are formed in the upper portion of the semiconductor layer structure 650. In the depicted embodiment, each p-well 630 has a hexagonal shape when viewed in plan view. Heavily-doped n-type source regions 640 are formed in each p-well 630 and may each have an annular hexagonal shape. Channel regions 632 are formed in the outer portions of the p-wells 630 outside the source regions 640. A heavily-doped p-type well contact region 638 is formed within each respective source region 640. The remainder of the upper surface of the semiconductor layer structure 650 may comprise a more lightly-doped JFET region 628. The dotted hexagons in FIG. 14A illustrate the regions of the upper surface of the semiconductor layer structure 650 where a source metallization layer of MOSFET 600 directly contacts the semiconductor layer structure 650. The dashed hexagons in FIG. 14A illustrate the regions of the upper surface of the semiconductor layer structure 650 that are not covered by a continuous gate electrode 670 of power MOSFET 600.

Referring to FIG. 14B, the semiconductor layer structure 650 of power MOSFET 600 includes a heavily-doped n-type substrate 610, a drift region 620, the p-wells 630, the source regions 640 and the well contact regions 638. A continuous gate dielectric layer 660 is formed over much of the upper surface of the semiconductor layer structure 650, and the continuous gate electrode 670 is formed on the gate dielectric layer 660. An intermetal dielectric layer 662 covers the upper and side surface of the gate electrode 670, and the source metallization layer 680 is formed on the intermetal dielectric layer 662 and on the exposed regions of the semiconductor layer structure 650. It will be appreciated that each of the above-described elements of power MOSFET 600 may have the same characteristics (e.g., doping type, doping concentration, depths) as the correspondingly named components of power MOSFET 200 of FIGS. 3A-3D, and hence further description of these elements will be omitted here.

As shown in FIG. 14B, the drift region 620 may have a super junction structure that includes a plurality of lower-doped n-type pillars 621, a plurality of higher-doped p-type pillars 622 and a plurality of higher-doped n-type pillars 623. The higher-doped p-type pillars 622 may each have a hexagonal shape when viewed in plan view. The lower-doped n-type pillars 621 and the higher-doped n-type pillars 623 may form a plurality of composite n-type pillars 624 in the same manner discussed above with respect to power MOSFET 200. The higher-doped p-type pillars 622 may be charge balanced with the composite n-type pillars 624 to form a super junction structure in the drift region 620. Thus, FIGS. 14A and 14B provide one representative example as to how the techniques disclosed herein may be implemented in a power MOSFET having a cell configuration.

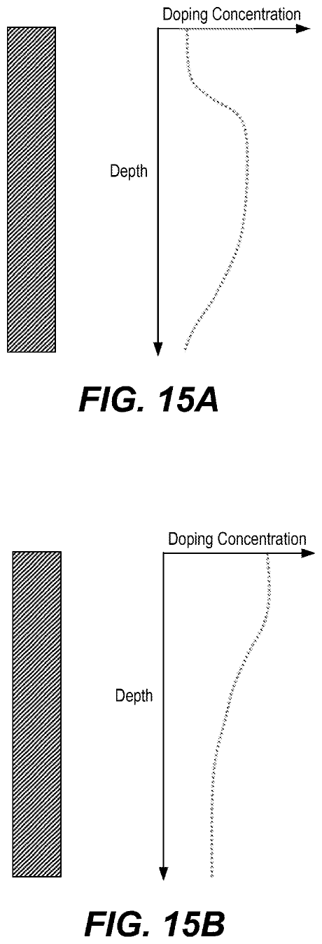

It will also be appreciated that the higher-doped p-type pillars (e.g., pillars 322, 422, 522) and the higher-doped n-type pillars (e.g., pillars 323, 423, 523) may have doping concentrations that vary as a function of depth in some embodiments. Typically, the variation in the doping concentration of the n-type pillars and the p-type pillars will be the same as a function of depth so that a quasi-charge balance may be maintained. Modulating the doing concentrations as a function of depth may allow the blocking voltage and on-state resistance performance of the device to be better controlled and/or be more scalable. FIGS. 15A and 15B illustrate two example graded doping profiles that can be used for the higher-doped p-type pillars (e.g., pillars 322, 422, 522) and the higher-doped n-type pillars (e.g., pillars 323, 423, 523).

As discussed above, the semiconductor devices according to embodiments of the present invention may have drift regions that include super junction structures where the super junction structure is formed independently of the unit cell structure in the upper portion of the active region of the semiconductor device. This allows the super junction structure to be designed independently of the unit cell structure of the device.

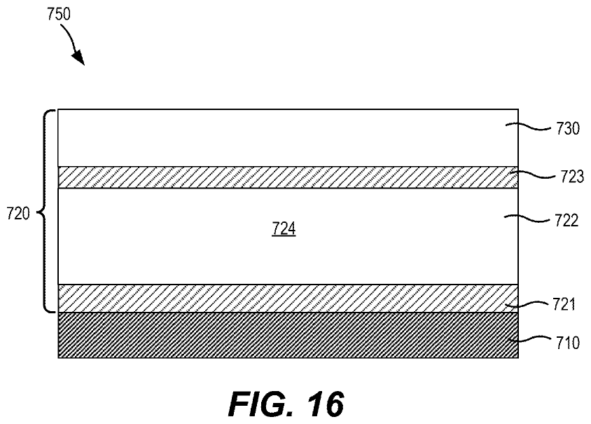

In some embodiments the super junction structure is formed independently of the unit cell structure by embedding the super junction structure within the drift region. For example, FIG. 16 is a schematic cross-sectional view of the semiconductor layer structure 750 of a semiconductor device according to embodiments of the present invention that has a super junction structure that is buried within the drift region. The semiconductor device may comprise, for example, a planar MOSFET, a trench gate MOSFET an IGBT, etc. so the metal, semiconductor and dielectric layers that are formed on the semiconductor layer structure 750 are omitted in FIG. 16.

As shown in FIG. 16, the semiconductor layer structure 750 includes a semiconductor substrate 710. A drift region 720 is formed (e.g., by epitaxial growth) on the semiconductor substrate 710. The unit cell structure of the semiconductor device is formed on the upper surface of the drift region 720. A unit cell structure 730 of the device is formed on and/or in the drift region 720. As shown in FIG. 16, the drift region 720 includes a lower portion 721, an upper portion 723, and a super junction portion 722 that is interposed between the lower portion 721 and the upper portion 723. The lower portion 721 may comprise a region having a first conductivity type that extends throughout the active region. The upper portion 723 may likewise comprise a region having the first conductivity type that extends throughout the active region. The super junction portion 722 includes a plurality of first conductivity type regions and a plurality of second conductivity type regions that are charge balanced with each other. The super junction portion 722 may include any appropriate super junction structure 724, such as, for example, fin-shaped super junction structures, checkerboard shaped super junction structures, concentric circle shaped super junction structures, etc. The super junction structure 724 may be arranged at any desired orientation, and may or may not be aligned with elements in the unit cell structure 730 of the semiconductor device. The super junction portion 722 and the super junction structure 724 formed therein are shown by a white box in FIG. 16 to illustrate that any super junction structure 724 that has any construction and orientation may be used. Likewise, the unit cell structure 730 of the semiconductor device is shown using a white box in FIG. 16 to illustrate that any appropriate unit cell structure may be used.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices such as MISFETs that include non-oxide gate dielectric layers.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure having an active region and a termination region, the semiconductor layer structure comprising:
a drift region; and
a plurality of well regions having a second conductivity type on the drift region, each well region comprising a channel region,
wherein the drift region comprises a lower portion having a first conductivity type, an upper portion having the first conductivity type, and a super junction structure between the lower and upper portions of the drift region.

2. The semiconductor device of claim 1, wherein the super junction structure comprises a plurality of pillars having the first conductivity type and a plurality of pillars having the second conductivity type.

3-6. (canceled)

7. The semiconductor device of claim 2, wherein the plurality of pillars having the first conductivity type comprise a plurality of first pillars that have the first conductivity type and a first doping concentration and a plurality of third pillars that have the first conductivity type and a third doping concentration, and wherein the plurality of pillars having the second conductivity type comprise a plurality of second pillars that have the second conductivity type and a second doping concentration.

8. The semiconductor device of claim 7, wherein the second and third doping concentrations exceed the first doping concentration.

9. (canceled)

10. A semiconductor device, comprising:
a semiconductor layer structure comprising a drift region, a plurality of well regions having a second conductivity type on the drift region, and a plurality of source regions having a first conductivity type on the well regions,
where the drift region comprises a first pillar that has the first conductivity type and a first doping concentration, a second pillar that has the second conductivity type and a second doping concentration, and a third pillar that has the first conductivity type and a third doping concentration, where the second and third doping concentrations exceed the first doping concentration, and the first, second and third pillars form part of a super junction structure in the drift region.

11. The semiconductor device of claim 10, wherein the first pillar is one of a plurality of first pillars that each have the first conductivity type and the first doping concentration, the second pillar is one of a plurality of second pillars that each have the second conductivity type and the second doping concentration, and the third pillar is one of a plurality of third pillars that each have the first conductivity type and the third doping concentration.

12-13. (canceled)

14. The semiconductor device of claim 11, wherein each first pillar contacts a respective one of the second pillars and a respective one of the third pillars.

15. The semiconductor device of claim 11, wherein each second pillar is in between and contacts first and second first pillars of a respective pair of the first pillars.

16. The semiconductor device of claim 11, wherein each third pillar is in between and contacts first and second first pillars of a respective pair of the first pillars.

17. The semiconductor device of claim 14, wherein each second pillar is in between and contacts first and second first pillars of a respective pair of the first pillars.

18. The semiconductor device of claim 17, wherein each third pillar is in between and contacts first and second first pillars of a respective pair of the first pillars.

19-22. (canceled)

23. The semiconductor device of claim 11, wherein each third pillar extends to an upper surface of the semiconductor layer structure, and each first pillar extends to a bottom surface of one of the well regions.

24-34. (canceled)

35. A semiconductor device, comprising:
a semiconductor layer structure comprising:
a drift region that comprises first and second lower-doped first pillars that have a first conductivity type, first and second higher-doped second pillars that have a second conductivity type, and a higher-doped third pillar that has the first conductivity type;
first and second well regions having the second conductivity type on the drift region; and
a gate dielectric layer on an upper surface of the semiconductor layer structure and contacting upper surfaces of the first and second well regions,
wherein the higher-doped third pillar is in between the first and second well regions and is in between and contacting the first and second lower-doped first pillars.

36-37. (canceled)

38. The semiconductor device of claim 35, wherein the first lower-doped first pillar vertically overlaps the first well region and the second lower-doped first pillar vertically overlaps the second well region.

39. (canceled)

40. The semiconductor device of claim 35, wherein the first and second lower-doped first pillars, the first and second higher-doped second pillars and the higher-doped third pillar together form a super junction structure in the drift region.

41. (canceled)

42. The semiconductor device of claim 35, wherein at least a portion of the first higher-doped second pillar is charge balanced with a portion of a composite pillar, where the composite column comprises the first and second lower-doped first pillars and the higher-doped third pillar.

43. The semiconductor device of claim 35, wherein the first and second higher-doped second pillars and the higher-doped third pillar each have respective doping concentrations that exceed a doping concentration of the first lower-doped first pillar by at least a factor of five.

44-47. (canceled)

48. The semiconductor device of claim 35, wherein a first source region having the first conductivity type is provided in the first well region and a second source region having the first conductivity type is provided in the second well region, and the first lower-doped first pillar vertically overlaps the first source region and the second lower-doped first pillar vertically overlaps the second source region.

49. The semiconductor device of claim 48, wherein the first higher-doped second pillar vertically overlaps the first source region and the second higher-doped second pillar vertically overlaps the second source region.

50. The semiconductor device of claim 49, wherein the first source region is closer to the higher-doped third pillar than is the first of the higher-doped second pillars.

51-79. (canceled)
